(19) United States
(12) Patent Application Publication
(10) Pub. No.: US 2024/0068964 A1
(43) Pub. Date: Feb. 29, 2024

(54) EVALUATING X-RAY SIGNALS FROM A PERTURBED OBJECT

(71) Applicant: NOVA LTD., Rehovot (IL)

(72) Inventors: Shahar Gov, Rehovot (IL); Daniel Kandel, Rehovot (IL); Heath POIS, Fremont, CA (US); Parker Lund, Sunnyvale, CA (US); Michal Haim YACHINI, Rehovot (IL); Vladimir Machavariani, REHOVOT (IL)

(73) Assignee: NOVA LTD., Rehovot (IL)

(21) Appl. No.: 18/260,036

(22) PCT Filed: Dec. 30, 2021
(86) PCT No.: PCT/IB2021/062502

§ 371 Date: Jun. 30, 2023

Related U.S. Application Data
(60) Provisional application No. 63/205,631, filed on Dec. 31, 2020.
(60) Provisional application No. 63/205,630, filed on Dec. 31, 2020.

(51) Int. Cl. G01N 23/20

(52) U.S. Cl. CPC G01N 23/20

(57) ABSTRACT

A method, a system, and a non-transitory computer readable medium for evaluating x-ray signals. The method may include calculating an estimated field for each of multiple non-perturbed objects, the multiple non-perturbed objects represent perturbances of the perturbed object; the perturbances are of an order of a wavelength of the non-diffused x-ray signals; and evaluating the non-diffused x-ray signals based on the field of the multiple non-perturbed objects.

### CROSS REFERENCE

This application claims priority from U.S. provisional patent 63/205,631 filing date Dec. 31, 2021 and from U.S. provisional patent 63/205,630 filing date Dec. 31, 2021—both provisional patents are incorporated herein by reference.

### BACKGROUND

In the x-ray regime, the roughness size is comparable to the wavelength.

FIG. 1 shows a typical line 11 whose edges 12 and 13 are rough and has a critical dimension (distance between edges 12 and 13) 15—in this case length of the line.

FIG. 2 illustrates an x-ray system that has an x-ray source 21 and optics that focus an x-ray beam 31 onto a small spot 33 on a sample 100, usually via a mirror that is represented in the figure symbolically as a lens 22. The reflected x-ray 32 from the sample is detected by a CCD camera 23 that is positioned at the far-field region. FIG. 2 also illustrates the illumination angle 41 and the collection angle 32.

The illumination cone may differ from the collection cone, with the latter being typically larger than the primer to allow for the detection of “scattered” X-Ray. These are rays that are diffracted from the sample not into the specular direction.

In this scheme, several scattering directions are collected simultaneously, by impinging on different pixels of the CCD camera, thus reducing the need for scanning the source/sample of sample/detector orientations or both.

This however means that the scattered rays that are produced from one incoming direction, may interfere at the detector with those scattered rays that are produced from another incoming direction.

When the roughness size is comparable to the wavelength the effect of the roughness on the detected signals is significant and should be taken into account—especially when using a model-based approach to interpret the detected signals.

### SUMMARY

There may be provided a system, a method and a non-transitory computer readable medium that stores instructions for evaluating x-ray signals from a perturbed object.

There may be provided a method for evaluating non-diffused x-ray signals received from a perturbed object due to an illumination of the perturbed object, the method may include: calculating an estimated field for each of multiple non-perturbed objects, the multiple non-perturbed objects represent perturbances of the perturbed object; the perturbances are of an order of a wavelength of the non-diffused x-ray signals; and evaluating the non-diffused x-ray signals based on the field of the multiple non-perturbed objects.

There may be provided a method, a system, and a non-transitory computer readable medium for evaluating x-ray signals. The method may include estimating a field generated by perturbances of the perturbed object, the perturbances are of an order of a wavelength of the x-ray signals, wherein the estimating comprises calculating a general function that is responsive to fields contributed by single perturbances of the perturbances of the perturbed object, the general function is applicable to perturbed objects of arbitrary shapes; and evaluating the x-ray signals based on the field, and one or more statistical properties of the perturbances.

### BRIEF DESCRIPTION OF THE DRAWINGS

In order to understand the invention and to see how it may be carried out in practice, a preferred embodiment will now be described, by way of non-limiting example only, with reference to the accompanying drawings:

FIG. 1 illustrates a prior art line;

FIG. 2 illustrates a schematic operation of prior art x-ray system;

FIG. 3 illustrates an example of reflectivity versus angle spectrum for a perturbed object and for a perturbed object;

FIG. 4 shows an example of structural element;

FIG. 5 illustrates an example of continuous perturbation over the surface;

FIG. 6 illustrates an example of possible interfaces that carry roughness;

FIG. 7 shows an example of non-diffused reflectance of a 4.47 nm wavelength;

FIG. 8 shows an example of perturbed object and multiple non-perturbed objects;

FIG. 9 shows an example of the simulated effect of roughness on a periodic structure;

FIG. 10 illustrates an example of a method;

FIG. 11 illustrates an example of a method;

FIG. 12 illustrates an example of signal versus grazing angle;

FIG. 13 illustrates an example of a method;

FIG. 14 illustrates an example of a perturbed object and a non-perturbed object;

FIG. 15 illustrates an example of a perturbed object and a non-perturbed object;

FIG. 16 illustrates an example of signal versus grazing angle;

FIG. 17 illustrates an example of a non-perturbed object;

FIG. 18 illustrates an example of a non-perturbed object;

FIG. 19 illustrates an example of a non-perturbed object;

FIG. 20A illustrates an example of signal versus grazing angle;

FIG. 20B illustrates an example of a method;

FIG. 21 illustrates a cross-sectional view of a periodic structure subjected to conventional scatterometry measurements using an incident beam having a single angle of incidence;

FIG. 22 illustrates a cross-sectional view of a periodic structure subjected to scatterometry measurements using an incident beam having multiple angles of incidence, in accordance with an embodiment of the present invention;

FIG. 23 illustrates a top-down view of a periodic structure subjected to conventional scatterometry measurements using an incident beam having a single azimuthal angle;

FIG. 24A illustrates a top-down view of a periodic structure subjected to scatterometry measurements using an incident beam having multiple azimuthal angles, with a central axis having a zero azimuthal angle, in accordance with an embodiment of the present invention;

FIG. 24B illustrates a top-down view of a periodic structure subjected to scatterometry measurements using an incident beam having multiple azimuthal angles, with a central axis having a non-zero azimuthal angle, in accordance with an embodiment of the present invention;

FIG. 25 illustrates aspects of exemplary fin-FET devices suitable for low energy X-ray reflectance scatterometry measurements, in accordance with an embodiment of the present invention;

FIG. 26 includes a plot and corresponding structures of 0th order reflectance versus scattered angle silicon (Si) fins having a periodic structure with 10 nm/20 nm line/space ratio, in accordance with an embodiment of the present invention;

FIG. 27 includes a plot and corresponding structures of 1st order reflectance versus scattered angle silicon (Si) fins having a periodic structure with 10 nm/20 nm line/space ratio, in accordance with an embodiment of the present invention;

FIG. 28 is an illustration representing a periodic structure measurement system having X-ray reflectance scatterometry (XRS) capability, in accordance with an embodiment of the present invention; and

FIG. 29 illustrates a block diagram of an exemplary computer system, in accordance with an embodiment of the present invention.

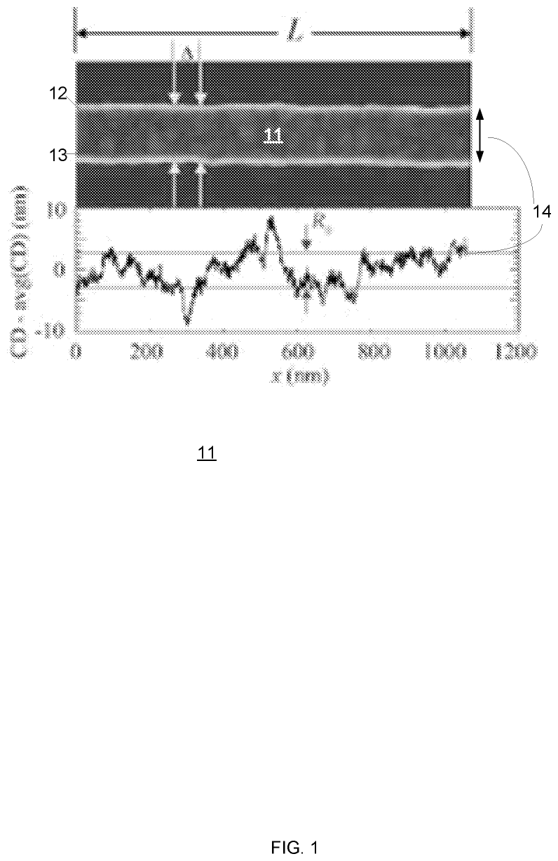

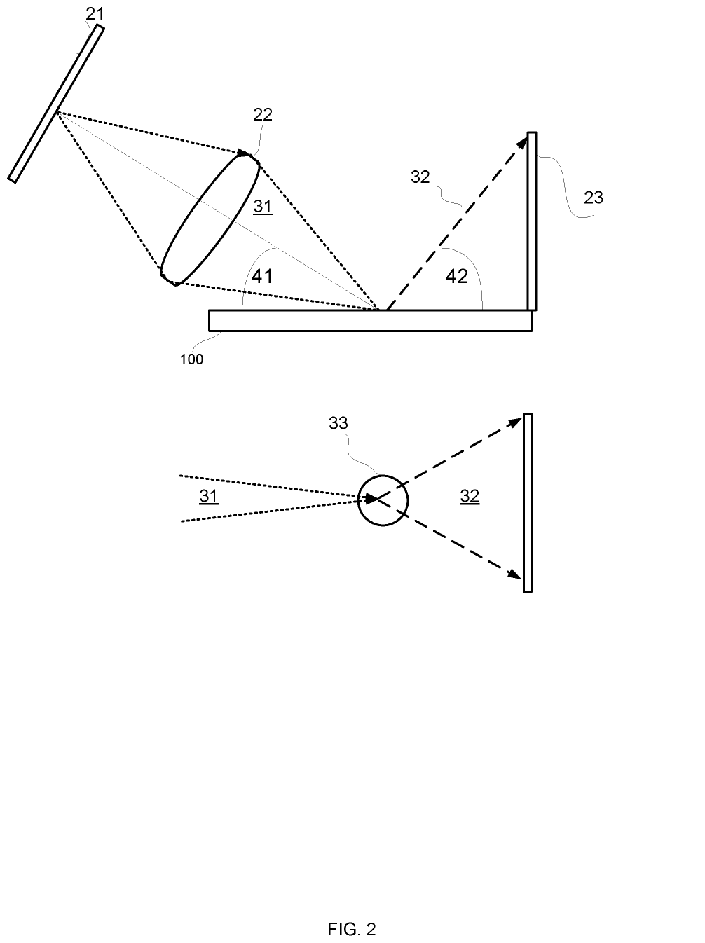

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Any reference in the specification to either one of a system, a method and a non-transitory computer readable medium should be applied mutatis mutandis to any other of the system, a method and a non-transitory computer readable medium. For example—any reference to a system should be applied mutatis mutandis to a method that can be executed by the system and to a non-transitory computer readable medium that may stores instructions executable by the system.

Because the illustrated at least one embodiment of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any number, or value illustrated below should be regarded as a non-limiting example.

The phrase “A based on B” may mean that A is solely based on B or that A is based on B and one or more other elements and/or parameters and/or information. Based on means that a calculation of A is affected by B and/or that the value of A is a function of the value of B.

The term “evaluation” may mean measurement, estimation, simulation, calculation, approximation, validation, generating a model, and the like.

Evaluating x-ray signals may include performing an evaluation of the x-ray signals that should be detected as a result of an illumination of an object.

The term “obtaining” may include generating, receiving, and the like. For example—receiving detection signals may include generating the detection signals, illuminating a perturbed object and generating detection signals, receiving or retrieving the detection signals without generating the detection signals, and the like.

The x-ray signals may be diffused x-ray signals and non-diffused x-ray signals. An evaluation based on non-diffused x-ray signals (and not on diffused signals) may be referred to a non-diffused evaluation. An evaluation based on diffused x-ray signals (and not on non-diffused signals) may be referred to a diffused evaluation.

A solid stack is a structure that include a stack of layers that are parallel to each other.

For simplicity of explanation most of the example refer to a rough surface that should have been (at the absence of roughness) horizontal, and various non-perturbed surfaces. It should be noted that the horizontal orientation is merely an example of an orientation and that the rough surface and non-perturbed surfaces may be oriented in any orientation. The reference to up, upper, top, lower, lowest and down should be applied to any orientation.

The suggested solutions are believed to be the first solutions that can be applicable to perturbed objects of arbitrary shape—and are not limited to a solid stack. The solutions may be applied, for example, to perturbed periodic structures and/or to perturbed pseudo-periodic (periodic up to a phase) structures—or to perturbed non-periodic structures.

Any reference to a structure should be applied mutatis mutandis to a structural element, to a sample, to a periodic structure, to a basic cell of a periodic structure, and an object. Various objects, structural elements, samples, or structures that are illustrated in various figures may form a grating or otherwise may arranged in a periodic manner. For example—structural element 61, may be a basic cell of a periodic structure.

There may be provided a system, a method, and a non-transitory computer readable medium that stores instructions for evaluation emission of x-ray signals from a perturbed object of arbitrary shape.

The terms perturbations and roughness are used in an interchangeable manner. A perturbed object is an object that suffers from roughness.

A perturbed surface or rough surface exhibits roughness at an order (for example between 10% to 1000%) of the wavelength of the x-rays. The wavelength of x-rays may range between 0.01 to 10 nanometers. Thus the perturbed surface may be of nanometric scale—for example between 0.01 nanometers and 80 nanometers, less than 0.01 nanometers or more than 80 nanometers. A single x-ray beam may forma spot that may concurrently illuminate multiple basic cells of a periodic structure.

A detector used to detect the x-ray radiation may be a two dimensional detector and its pixels may be classified to diffused pixel for sensing diffused radiation and non-diffused pixels for sensing non-diffused radiation. The classification may per object and/or per illumination and/or detection scheme.

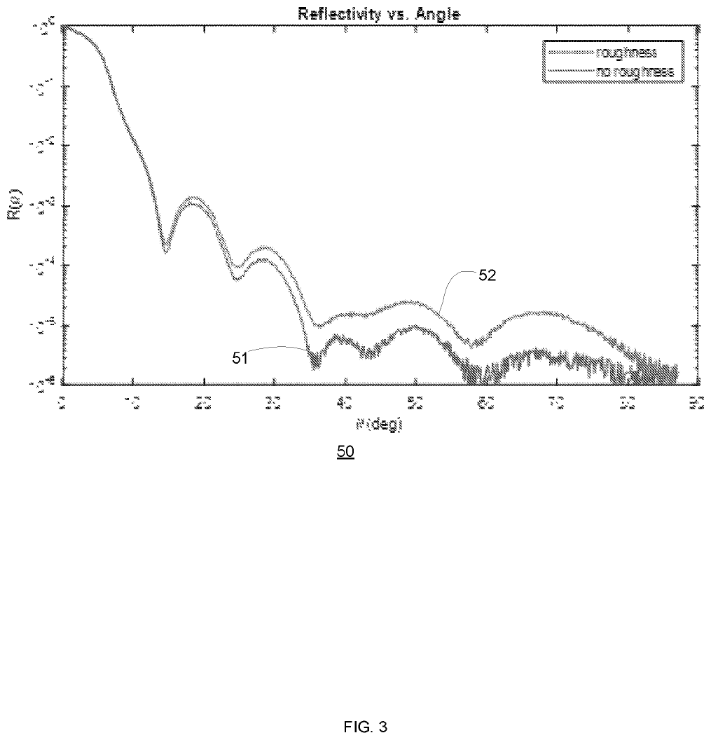

FIG. 3 includes graph that illustrates an example of a simulation describing how the reflectance (ratio of reflected intensity to incoming intensity) of x-ray from a solid stack sample changes as roughness is turned on (rough solid stack) or off (smooth solid stack)—see curves 51 and 52 respectively.

FIG. 3 shows the reflectance as a function of elevation angle—theta, assuming both the source and the detector are producing/capturing light via a very narrow illumination/collection cone. Since this is a solid stack, the reflected signal is mostly in the specular direction, so the angle of reflection is equal to the angle of illumination, hence a single angle theta is needed to parameterize the graph. Not shown in the graph is the reflectance to non-specular directions, though these are also present when roughness exists.

There is a need to characterize also periodic (non-solid) structures that contain roughness, an algorithm that evaluates the response of a periodic sample, possessing roughness on its interfaces, to an illumination by x-ray is needed.

Derivation of the Scattered E-Field for an Isolated Small Perturbation.

The reflectance as well as the inner fields of the roughness-free (i.e. without perturbation) periodic sample is first evaluated by a rigorous well-known solution of the electromagnetic scattering problem. These are evaluated for two different directions and polarization of illumination—the arbitrary incoming ray, and the direction of the reverse of an arbitrary outgoing direction.

In the case of an illumination/collection with finite cones (or other finite shapes), superposition is employed to add up the contribution from each single direction separately.

The inner E-field vector at a specific point (rₜ,t) inside the structural element for a given illumination direction k_{inc}, and input polarization state p_{inc} is denoted below by:

Ē( [symbol] , [symbol] →rₜ,t) (0)

Note again that this field is evaluated for the unperturbed structural element. We show below, that for a complete determination of the effect of roughness, and under the assumption of “small” perturbation, one needs two different inner E-fields:
a. The inner field—at point (rₜ,t)—produced when illumination (with unit amplitude and zero phase as measured at the reference point O) is coming from the actual illumination direction k_{inc}, and input polarization state p_{inc} the format goes as follows:

Ē( [symbol] , [symbol] →rₜ,t) (1)
b. The inner field—at point (rₜ,t)—produced when illumination (with unit amplitude and zero phase as measured at the reference point O) is coming from the reverse of the collection direction k_{sc}, and output polarization state p_{sc}:

Ē( [symbol] , [symbol] →rₜ,t) (2)

To illustrate how these two field are used to determine the diffracted signal from a perturbed profile (not necessarily probabilistic), we first illustrate how it is accomplished for a profile that has been perturbed by a small, isolated volume.

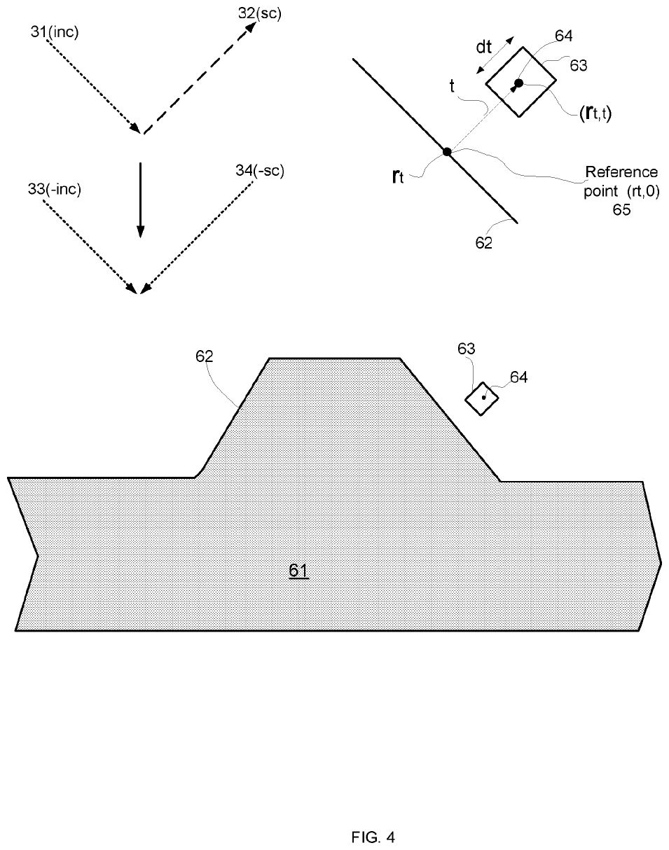

FIG. 4 shows a structural element that is mostly non-perturbed and is made of a first material, that interfaces a surrounding having a surrounding material that differs than the first material (representing say air). We assume an object includes repetitions of the structural element—for example periodic repetitions along the horizontal direction, with only a single period depicted in the FIG. 4.

The structural element 61 has an exterior surface that is smooth and may be referred as nominal surface 62 (in FIG. 4 this is illustrated as a top surface) that has a leftmost horizontal part, followed by a positive sloped part, followed by another (higher) horizontal part, followed by negative sloped part that is followed by a rightmost horizontal part.

FIG. 4 illustrates an example of a reference point 65 located on the negative sloped part—at coordinates (rₜ,0)—which has fields Ē( [symbol] , [symbol] ) and Ē( [symbol] , [symbol] ). The fields at the reference point are illustrated above. The first coordinate rₜ represents a location (for example a two dimensional coordinate) on exterior surface and the second coordinate t is a distance from the surface—at point rₜ. The second coordinate is a distance along a normal to surface 65 at coordinate rₜ.

This structural element is slightly perturbed by adding a new element 63 of a small volume (in relation to the volume of the structural element 61).

The geometry of the new element 63 is represented by specifying the projection of its “center of mass” 64 onto the nearest boundary surface (at coordinate rₜ), and by the distance of its center from that surface (denoted by the 1D coordinate t). The new element 63 has a very small (differential) base area denoted by d²rₜ (oriented parallel to the inclined surface in the FIG. 4), and a small (differential) height dt (measured normal to the surface).

Instead of evaluating the radiation that will be emitted from the structural element and impinge on a point on the detector—the evaluation will take into account “inverse” radiation that will virtually impinge (denoted 33) on the structural element from the point of the detector and will be virtually “inverse” emitted (scattered—denoted 33) from the structural element towards the illumination source.

In FIG. 4 radiation that impinges on the structural element is denoted 31, radiation emitted (for example scattered) from the structural element is denoted 32.

With these notations, The Fourier component of the complex-valued scattered field (amplitude and phase), that is being scattered into direction k_{sc} with polarization state p_{sc}, as measured at the reference point O, when a unit amplitude zero phase Field component (as measured at the same reference point O) is illuminating the sample from direction k_{inc} with polarization state p_{inc} is given (under “small” perturbation approximation), via the expression:

$$\overline{E} ( , \to , ) = {E}_{Unpertrubed} + \frac{{ik}_{0}^{3}}{8 {π}^{2} {ε}_{0}} dt * {d}^{2} {r}_{t} * ( {ε}_{New} - {ε}_{Old} ) * \overline{E} ( , - \to {r}_{t} , t ) * \overline{E} ( , \to {r}_{t} , t ) \qquad ( 3 )$$

In this expression:
E_{Unperturbed} is the field that would be produced when the perturbation is absent.
i is the unit imaginary complex number.
k₀ is the wavenumber that is related to the wavelength λ via the relation

$${k}_{0} = \frac{2 π}{λ} .$$

ε₀ is the permittivity of the vacuum.
ε_{Old} is the permittivity of the material at the volume where the perturbation was introduce before it was introduced.
ε_{New} is the permittivity of the material at the volume where the perturbation was introduce after it was introduced.

We will later use a shorthand notation for the difference between the two permittivities:

Δε=ε_{New}−ε_{Old} (4)

Note that this difference may, in general, depend on (rₜ,t).

Equation (3), also known as the “Born first order approximation”, is valid provided that the perturbation is “small enough”. More precisely, the condition for its validity is given by:

$$\frac{{k}_{0}^{3}}{8 {π}^{2} {ε}_{0}} {d}^{2} {r}_{t} dt = \frac{{k}_{0}^{3}}{8 {π}^{2} {ε}_{0}} \{ Volume of pertubation \} ≪ 1 \qquad ( 5 )$$

Use of Superposition to Generalize for the Case of a Continuous Perturbation

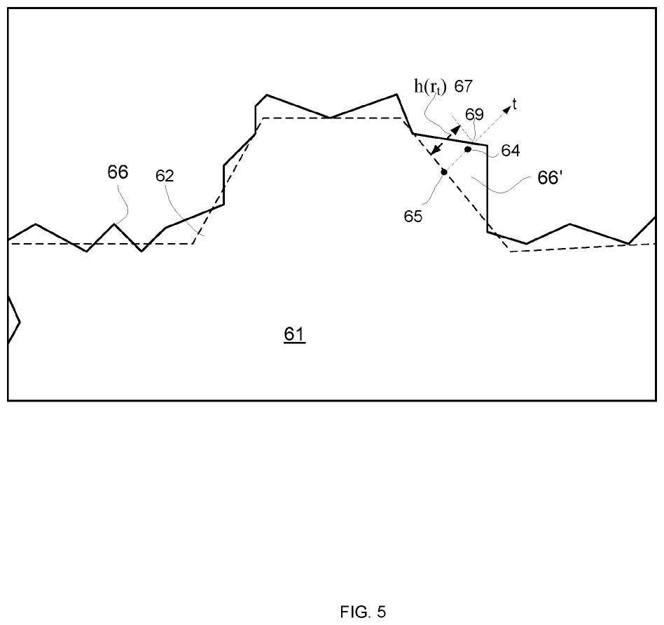

When one considers the case of a continuous perturbation over the surface, such as a an example depicted in FIG. 5.

The structural element 61 is perturbed—which is represented by a nominal surface 62 (which is not perturbed) and deviations (perturbations) from that non-perturbed surface.

The deviations may include, for example perturbance 66 and another perturbance 66′ that includes multiple new elements—such as the new element of FIG. 4—being represented by center of gravity 64 and reference point 65.

One can break this into a collection of many non-overlapping “cubes” that comprises the continuous geometry of the perturbation such that it is fully covered. Under the 1^{st} Born approximation, in such a case the individual scattered fields that are produced by each of these collections of cubes can be superimposed {summed} to give the overall field that is produced.

This summation is represented mathematically by an integration of the coordinates (rₜ,t) where the 2D coordinate rₜ is integrated over the whole nominal surface 62 (of the entire object—for example—if the object is a periodic structure—than the coordinate may be integrated over the entire periodic structure), while the coordinate t (which is measured normal to the nominal surface) is integrated normal from its value at the surface (t=0) up to the distance away from the surface at which the perturbation is spanned (for example referring to reference point 65—the height h(rₜ) 67 equals the distance from point 69 (the exterior point of the perturbance along normal to nominal surface 62 that extends from reference point 65).

Since that height above (positive values)/below (negative value) the nominal surface 62 depends on the nominal location rₜ, the height h itself is a function of rₜ, hence h=h(rₜ). Thus, the overall field scattered by the perturbation profile is given by equation (6):

$$\overline{E} ( , \to , ) = \frac{{ik}_{0}^{3}}{8 {π}^{2} {ε}_{0}} {\int \int }_{Sur} {d}^{2} {r}_{t} {\int }_{0}^{h ( {r}_{t} )} dt * Δε * \overline{E} ( , - \to {r}_{t} , t ) * \overline{E} ( , \to {r}_{t} , t ) \qquad ( 6 )$$

Where “Sur” is the surface of the perturbed object. Note that in this expression, h(rₜ) may acquire either positive or negative values, to represent perturbation that are above or below the nominal interface boundary. The value of Δε will acquire an appropriate sign change to faithfully represent the difference in permittivity constant above/below the boundary.

Equation (6) calculates the field for a combination of a certain illumination angle and a single collection angle. Equation (6) may be calculated for different combinations of collection angle and illumination angle. For example—assuming that the x-ray radiation has a certain Numerical Aperture—then the fields at a certain collection angle can be the sum of electrical fields contributed due to different illumination angles within the Numerical Aperture of the x-ray radiation.

Taking into account different combinations of illumination angles and collection angles may be applied mutatis mutandis to all calculations (for example intensity calculations) of the specification.

Evaluating the Intensity from the E-Field, and Applying Randomness, and Ergodicity

The intensity that is associated with the scattered E-field that is derived above can now be evaluated by multiplying the field by its complex conjugate.

I(inc→sc)=E(inc→sc)*E*(inc→sc) (7)

Where we changed the long notation of the function arguments (\hat{p}_{inc}, \hat{k}_{inc}→\hat{p}_{sc}, \hat{k}_{sc}) to the shorter one (inc→sc). Hence, for a given deterministic perturbation profile, there is an associated intensity.

With the assumption that the area on the sample that is being illuminated being very large (for example—of micron scale), one can assume that the spot “covers” many different possible profiles (of nanometric scale) (with each profile belong to another part of the sample, say to another pitch).

We can consider this variations of profiles as a random effect—representing the probabilistic nature of a rough profile, and further assume that the large size of the spot justifies the assumption that all possible random profiles, drawn from a given statistics, are present in the illuminated area of the sample, and hence the actual intensity one is expected to measure is an average of the intensity over “all possible random profiles”. This assumption, which introduces randomness to the analysis, is termed henceforth as the ergodic assumption.

We will be using the following mathematical notation to represent this averaging:

[symbol]

* [symbol] ₕ₍ᵣ_{ₜ}₎={Average of*over all possible random profiles h(rₜ)} (8)

And with this notation, the intensity under the Ergodic assumption is given by:

Iₐᵥ(inc→sc)= [symbol] E(inc→sc)*E*(inc→sc) [symbol] ₕ₍ᵣ_{ₜ}₎ (9)

Separation of the Intensity into a “Diffuse” Term, and a “Non-Diffused” Term, and their Properties.

The intensity is therefore shown to be the average of the product of E-fields. By adding and subtracting the product of the average of the fields, we can recast the expression for the intensity as a sum of two terms, shown in equations (10):

$${I}_{av} ( inc \to sc ) = {〈 E ( inc \to sc ) * {E}^{*} ( inc \to sc ) 〉}_{h ( {r}_{t} )} = {I}_{Diffued} ( inc \to sc ) + {I}_{Non - Diffused} ( inc \to sc ) \qquad ( 10 )$$

$$\begin{matrix}{I}_{Diffued} ( inc \to sc ) = {〈 E ( inc \to sc ) * {E}^{*} ( inc \to sc ) 〉}_{h ( {r}_{t} )} - \\ {{〈 E ( inc \to sc ) 〉}_{h ( {r}_{t} )} * 〈 {E}^{*} 〈 inc \to sc ) 〉}_{h ( {r}_{t} )}\end{matrix}$$

$${I}_{Non - Diffused} ( inc \to sc ) = {〈 E ( inc \to sc ) 〉}_{h ( {r}_{t} )} * {〈 {E}^{*} ( inc \to sc ) 〉}_{h ( {r}_{t} )}$$

The reflected signal in the presence of roughness can thus be broken up to two additive terms:
a. The “Non-Diffused” intensity—which carry the effect of the roughness-related mean-field squared on the diffraction orders only.
b. The “Diffused” intensity—Which describes the effect of roughness-related field-field covariance.

The conclusion is that while the “Diffused” term depends only on the statistics of roughness at each point along the boundary, independently of the statistics at any other point, the “Non-Diffused” terms depends also on the correlation of roughness between any two points along the boundary.

As the “Non-Diffused” term is the summation of functions, each of which solely depends on a perturbation at a single point along the boundary, the correlation between any two perturbations along the surface is not taken into account in this term, and hence this term can be computed as if any two such perturbations are fully correlated. This correlation drastically ease the evaluation of this term, as it allows to evaluate the effect of roughness without lifting the periodicity assumption, and therefore affect only the intensity of the diffraction orders, but otherwise has no additional signal into directions that are not part of the diffraction orders. This property is further explained below.

In contrast, the “Diffused” term is proportional to the field-field covariance and hence does include correlations, and more statistics of the random profile is required in order to evaluate this term.

This difference between the two terms also affects the angular dependence of the scattered intensity of each term, for a given incidence direction:
a. The “Non-Diffused” term has no contribution to the scattering directions that are not part of the usual (perturbation-free) diffraction order directions of the sample.
b. The “Diffused” term contributes scattering into generally any arbitrary directions.

Expressing the Intensity in Terms of the Statistical Properties of the Random Profile.

Evaluating of the Non-Diffused Term

The expression for the Non-Diffused term requires the evaluation of the average of the E-field over all possible random profiles of deviations from the boundary:

[symbol]

E(inc→sc) [symbol] ₕ₍ᵣ_{ₜ}₎ (11)

This averaging can be evaluated from the dependence of the fields Ē(inc→rₜ,t) and Ē(sc→rₜ,t): As each of these fields can be expanded in a Fourier series when viewed as a function of t, their dot-product Ē(inc→rₜ,t)·Ē(sc→rₜ,t)—which is essentially the term that enters the perturbation in equation (6)—can—according to the convolution theorem—also be recast in this form, with the amplitudes of each frequency, and the frequencies themselves being derived from the solution of the unperturbed problem. Hence:

Ē(sc→rₜ,t)*Ē(inc→rₜ,t)=Σ_{n=-∞}^{+∞}Aₙ(rₜ,inc,sc)*e^{(ik}^{ₙ}^{(r}^{ₜ}^{,inc,sc)*t)} (12)

Where:

Aₙ(rₜ,inc,sc) is the amplitude of the Fourier component corresponding to the point rₜ along the boundary, for given incidence (inc) and scattered (sc) directions. Its numerical value can be retrieved by solving the unperturbed problem.
kₙ(rₜ,inc,sc) is the frequency of the Fourier component corresponding to the point rₜ along the boundary, for given incidence (inc) and scattered (sc) directions. Its numerical value can also be retrieved by solving the unperturbed problem.

For a periodic structure, the field can be expressed as a sum of discrete (rather than continuous) set of frequencies. The index n is used to enumerate these discrete set.

The expression in Equation (12) still needs to be integrated over t (from 0 to h), over rₜ, and then it needs to be averaged overall possible values of h. Assuming the probability density function of h is known and is given by ƒ(h), the average E-Field can then be evaluated via equation (13):

$${〈 E ( inc \to sc ) 〉}_{h ( {r}_{t} )} = \frac{i {k}_{0}^{3} Δ ε}{8 {π}^{2} {ε}_{0}} \int {\int }_{Sur} {d}^{2} {r}_{t} {\int }_{- ∞}^{∞} dhf ( h ) {\int }_{o}^{h} dt * \overline{E} ( sc \to {r}_{t} , t ) * \overline{E} ( inc \to {r}_{t} , t ) \frac{- i {k}_{0}^{3} Δ ε}{8 {π}^{2} {ε}_{0}} \text{} \int {\int }_{Sur} {d}^{2} \text{} {r}_{t} \text{} {\int }_{- ∞}^{h ( {r}_{t} ) ∞} dhf ( \text{} h ) \text{} {\int }_{o}^{h} dt * {\sum }_{n = - ∞}^{+ ∞} {{A}_{n} ( {r}_{t} , inc , sc )}^{( {ik}_{n} ( {r}_{t} , inc , sc ) * t )} \qquad ( 13 )$$

In general, the integral over h can be evaluated numerically, but there are cases in which it can be evaluated analytically. For example, if ƒ(h) is a Gaussian distribution function with mean 0 and standard deviation σ, then the integrals over t and h in equation 10, can be evaluated analytically and expressed in terms of Aₙ(rₜ,inc,sc) and kₙ(rₜ,inc,sc)—Both of which are known from the solution of the unperturbed problem.

Evaluating of the Diffused Term

This term requires a more complicated evaluation. It is proportional to the covariance of the field, and hence involves the correlation of perturbation between any two point along the boundary. One therefore needs to also to know the function g(h,h′; rₜ,rₜ′)—The joint probability function that the perturbation at point rₜ along the boundary is between h and h+dh and at point rₜ′ is between h′ and h′+dh′. This is also a characteristic of the rough boundary. With this function, the average of field-field product (which is part of the definition of the field-field covariance) can then be evaluated using equation (14):

$${〈 E ( inc \to sc ) * {E}^{*} ( inc \to sc ) 〉}_{h ( {r}_{t} )} = {\vert \frac{i {k}_{0}^{3} Δ ε}{8 {π}^{2} {ε}_{0}} \vert}^{2} \int {\int }_{Sur}^{a} {d}^{2} {r}_{t}^{′} * \int {\int }_{Sur}^{a} {d}^{2} {r}_{t} {\int }_{- ∞}^{∞} {dh}^{′} {\int }_{- ∞}^{∞} dhg ( h , {h}^{′} ; {r}_{t} , {r}_{t}^{′} ) x {\int }_{0}^{{h}^{′}} {dt}^{′} {\int }_{o}^{h} dt [ {\sum }_{n = - ∞}^{+ ∞} {A}_{n} ( {r}_{t} , inc , sc ) * {e}^{( {ik}_{n} ( {r}_{t} , inc , sc ) * t )} * {\sum }_{m = - ∞}^{+ ∞} {A}_{m}^{*} ( {r}_{t}^{′} , inc , sc ) * {e}^{( {ik}_{m} ( {r}_{t}^{′} , inc , sc ) * {t}^{′} )} ] \qquad ( 14 )$$

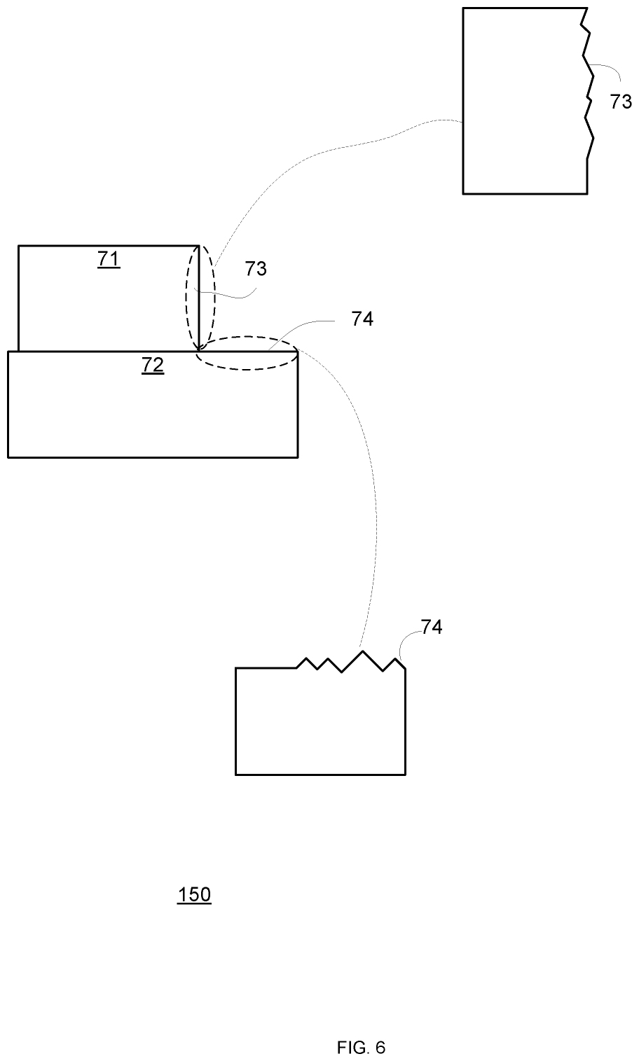

An example for two possible interfaces that carry roughness is shown in FIG. 6. A first part 71 of an object has a first rough surface 73 and a second part 72 of the object has a second perturbed surface 74.

Due to superposition, the case of a structural element having roughness both along a vertical boundary (or several such boundaries) and horizontal boundary (or several such), is accounted for by adding the contributed intensities from each boundary separately (assuming roughness between two points that belong to two different boundaries—are uncorrelated).

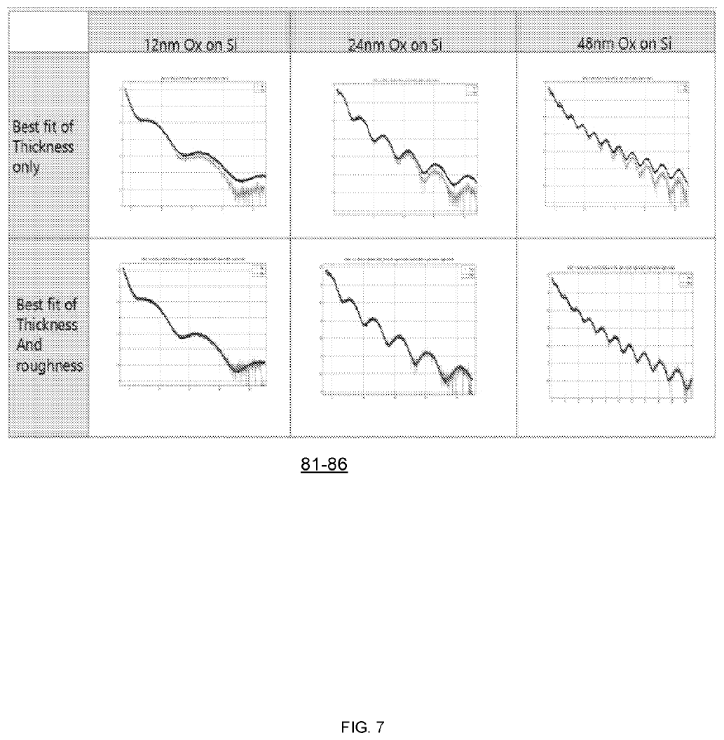

FIG. 7 includes graphs 81-86 that illustrate examples of non-diffused reflectance of a 4.47 nm wavelength from roughness carrying samples of roughness comprising of an oxide layer with different thicknesses deposited on a silicon substrate. The graphs shows both measurements and simulations, and stress the need to introduce roughness in order to properly model the observed effect of roughness

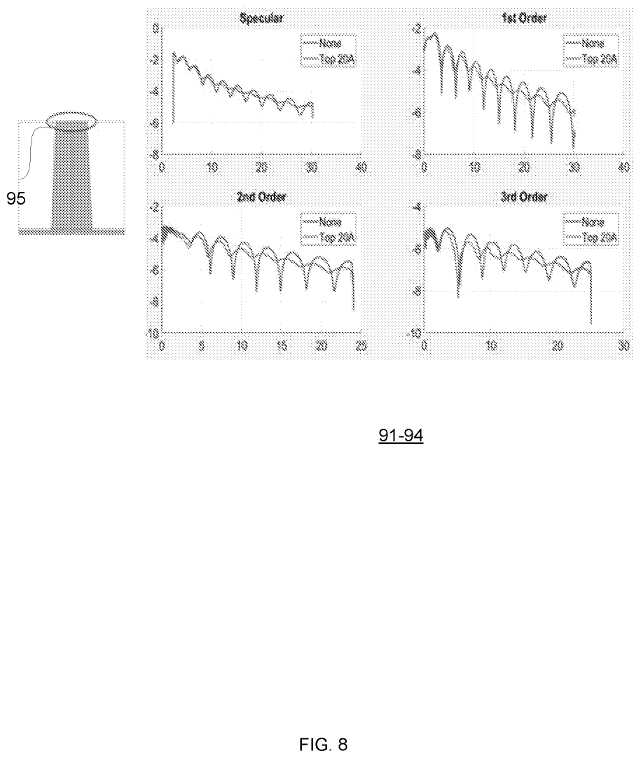

FIG. 8 shows the simulated effect (see curves 91 smooth top surface and 94 represents roughness of top surface of standard deviation 20 Angstrom) of examples of roughness on a periodic structure the structure 95 is made of lines of oxide etched over silicon substrate. The upper most top interface of the line carries roughness, and the effect of the non-diffused part of the signal on all the diffraction orders is shown compared to the roughness-free case.

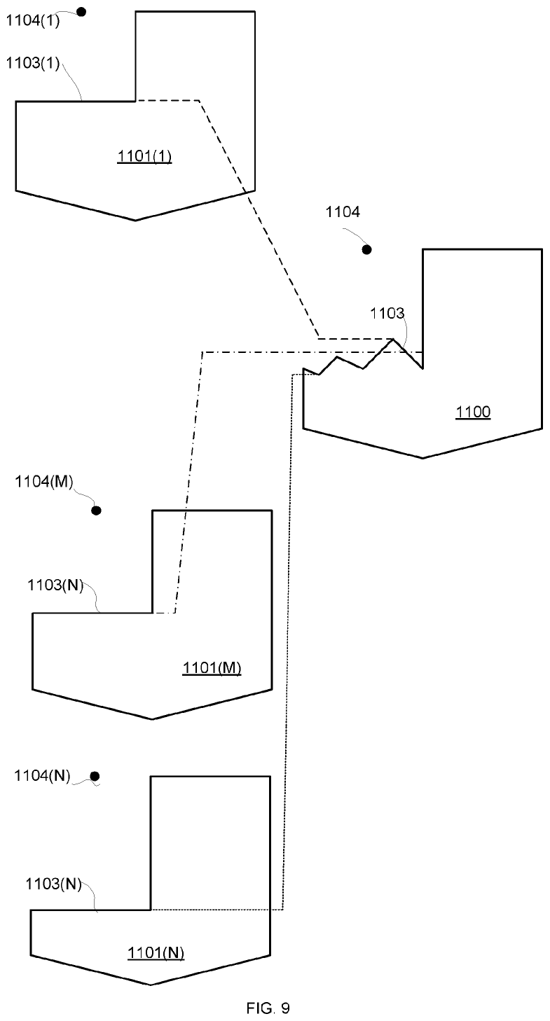

FIG. 9 illustrates an example of a method 200.

Method 200 may be for evaluating x-ray signals received from a perturbed object due to an illumination of the perturbed object.

The model may be used for various purposes—for example by determining a roughness of a perturbed object.

For example—reference models of perturbed objects of different roughness values may be generated. Once an evaluated perturbed object is evaluated—the x-ray signals received from the evaluated objects may be compared to the reference models—in order to find one or more similar reference models. The roughness of the evaluated perturbed object may be determined based on the roughness of the one or more similar reference models.

Method 200 may start by step 210 of estimating a field generated by perturbances of the perturbed object. The perturbances are of an order of a wavelength of the x-ray signals.

Step 210 may include calculating (step 220) a general function that is responsive to fields contributed by single perturbances of the perturbances of the perturbed object.

The general function is applicable to perturbed objects of different shapes—for example of arbitrary shapes. It is not applicable only to a perturbed object that include multiple layers that are parallel to each other.

Step 220 may include at least some of steps 221, 222, 223 and 224.

Step 221 may include calculating the general function by integrating a first integrable function that is unrelated to a shape of the perturbed object.

Step 221 may include integrating a first integrable function that is based on (a) a difference (Δε) between permittivity coefficients of the perturbed object and its surroundings at a location of one of the single perturbances, (b) a field (see equation (1)) contributed to an illumination of the one of the single perturbances at an illumination angle, and (c) a field (see equation (2)) contributed to a collection of illumination from the single perturbances and at a certain collection angle.

Referring to equation (6)—the first integrable function may be dt*Δε*Ē( [symbol] ,− [symbol] →rₜ,t).

The field contributed to the collection of illumination from the single perturbances and at a certain collection angle is calculated by calculating a field contributed to the illumination of the one of the single perturbances from an illumination angle that is opposite to the angle of collection. See, for example Ē( [symbol] ,− [symbol] →rₜ,t).

Step 222 may include calculating the general function by (a) first integrating a first integrable function over a height range that represents a height of the one of the single perturbances in relation of an unperturbed version of the perturbed object to provide a second integrable function. See, for equation (6)—the first integral between o and h(rₜ).

Step 223 may include a third integrable function, based on the second integrable function and an area of a normal projection of the one of the single perturbances on a non-perturbed version of a surface of the perturbed object. The area may be denoted d²rₜ in equation (6).

Step 224 may include second integrating the third integrable function over one or more surfaces of the perturbed object to provide a fourth function and adding to the fourth function an estimate of a field resulting from illuminating an unperturbed version of the perturbed object. See, for equation (6) the double integral over the nominal interface surface

$$\int {\int }_{{Nominal}_{{interface}_{surface}}} {d}^{2} {r}_{t} .$$

Step 220 may be followed by step 240 of performing an evaluation based on the field, and one or more statistical properties of the perturbances.

Step 240 may include at least one of steps 241, 242, 243, 244, 245, 246 and 247.

Step 241 may include evaluating a roughness of the perturbed object.

Step 242 may include evaluating the x-ray signals generated from perturbed object having a given roughness.

Step 243 may include determining one or more other properties (not roughness) of the perturbed object.

Step 244 may include validating roughness estimates.

Step 245 may include evaluating an intensity of the x-ray signals based on the field, and statistics of the perturbances of the perturbed object.

Step 246 may include calculating a diffused intensity and calculating a non-diffused intensity.

Step 247 of calculating a non-diffused intensity by averaging of the field obtained over possible perturbed versions of the perturbed object. See, for example [symbol] E(inc→sc) [symbol] ₕ₍ᵣ_{ₜ}₎

Step 247 may include calculating multiple integrals over various functions, wherein the calculating of the multiple integrals comprises calculating an initial integral between dot product of (a) a field contributed to an illumination of the one of the single perturbances at an illumination angle, and (b) a field contributed to a collection of illumination from the single perturbances at a certain collection angle.

Step 247 may include calculating the dot product by calculating a Fourier series that represents the dot product.

The x-ray signals may be diffused x-ray signals and step 240 may include calculating the intensity of the diffused x-ray signals.

The x-ray signals may be non-diffused x-ray signals and step 240 may include calculating the intensity of the non-diffused x-ray signals.

Step 240 may include validating or determining the intensity of non-diffused x-ray signals based on the intensity of diffused x-ray signals.

Step 240 may include validating or determining the intensity of diffused x-ray signals based on the intensity of non-diffused x-ray signals.

Step 240 may include determining a property of the perturbed object based on the intensity of non-diffused x-ray signals and the intensity of diffused x-ray signals.

Method 200 may be executed based on real illumination ofa real perturbed object.

Additionally or alternatively—method 200 may be executed based on simulating illumination of a perturbed object.

Method 200 may be executed multiple times on perturbed objects (simulated or real) having different roughness—to provide estimates of x-ray signals obtained when illuminating perturbed objects of different roughness.

These estimates may be used to determine the roughness of a newly evaluated perturbed object.

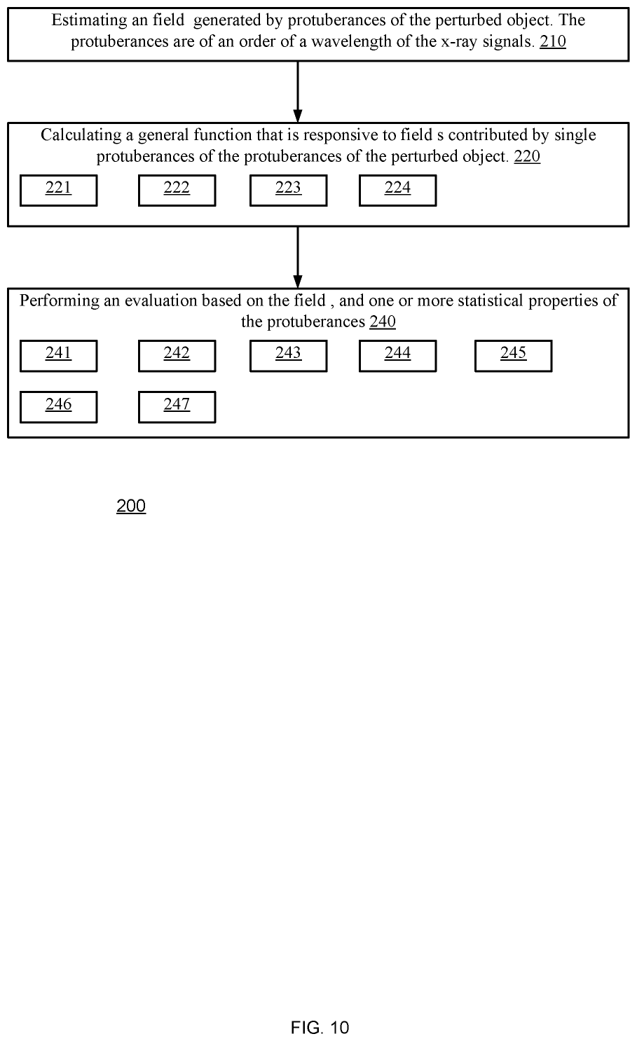

FIG. 10 illustrates an example of method 300 for evaluating non-diffused x-ray signals received from a perturbed object due to an illumination of the perturbed object.

Method 300 may include step 310 of calculating multiple non-perturbed objects represent perturbances of the perturbed object. The perturbances of the perturbed object are of an order of a wavelength of the non-diffused x-ray signals.

Step 310 may be followed by step 320 of calculating an estimated field for each of the multiple non-perturbed objects, the multiple non-perturbed objects represent perturbances of the perturbed object.

Step 320 may be followed by step 330 of evaluating the non-diffused x-ray signals based on the field of the multiple non-perturbed objects.

The perturbed object and each of the multiple non-perturbed objects interfaces may have a uniform permittivity.

The perturbances of the perturbed object may follow a perturbances distribution function. Step 310 may include calculating the multiple non-perturbed objects are calculated based on the perturbances distribution function.

The perturbances distribution function may be a probabilistic function of a height parameter of the perturbances of the perturbed object.

The height parameter of a given protuberance that is related to an interface of the perturbed object is a distance between the protuberance and the interface of the perturbed object, wherein the given protuberance belongs to the perturbances.

The perturbed object may have a single rough interface. The multiple non-perturbed objects may have corresponding non-perturbed interfaces, one corresponding non-perturbed interface per each non-perturbed object of the multiple non-perturbed objects.

A perturbances distribution function of the height parameter of perturbances of the single rough interface may be substantially equal to a perturbances distribution function of the height parameter of the corresponding given non-perturbed interfaces.

The perturbed object may have a plurality of rough interfaces. In this case the multiple non-perturbed objects have corresponding non-perturbed interfaces, a plurality of corresponding non-perturbed interface per each non-perturbed object of the multiple non-perturbed objects. The multiple non-perturbed objects may have different non-perturbed surfaces that represents combinations of the perturbances distribution functions of the plurality of rough interfaces. Different combinations of locations of non-perturbed interfaces that represents different rough interfaces should be evaluated.

FIG. 9 illustrates an example of multiple (N) non-perturbed objects 1101(1)-1101(N)—having non-perturbed surfaces 1101(1)-1103(N) respectively (one per non-perturbed object)—that represent perturbed object 1100 having perturbed surface 1103. The multiple non-perturbed objects are illustrated as including non-perturbed object 1101(M) having non-perturbed surface 1101(M).

In FIG. 9—the points along the perturbed surface 1103 are distributed (for example have y-axis coordinates) by a height distribution. The height of the non-perturbed surfaces 1101(3)-1103(N) may follow the height distribution of the perturbed surface.

The height of non-perturbed surface 1103(1) represents the highest point of the perturbed surface 1101.

The height of non-perturbed surface 1103(N) represents the lowest point of the perturbed surface 1101.

The height of non-perturbed surface 1103(M) represents an intermediate point of the perturbed surface 1101.

In FIG. 9 there is single instance of the highest point, a single instance of the lowest point and two instances the intermediate height. This may be represented by the number of non-perturbed objects allocated per each height, by a weight associated with calculations related to each height, and the like.

FIG. 9 also illustrates points 1104 and 1104(1)-1104(N) in which the field is calculated. The field may be calculated at any reference point.

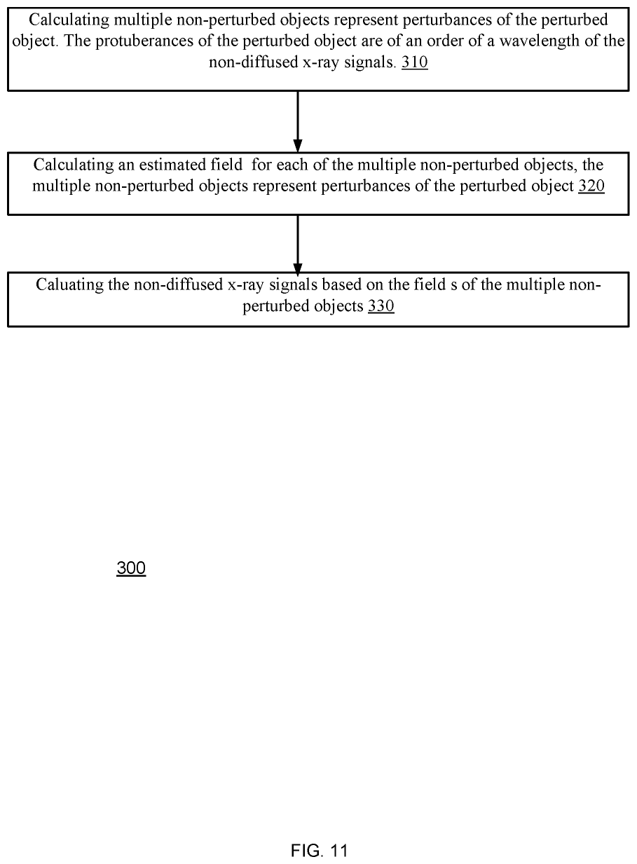

FIG. 11 illustrates an example of method 300 for evaluating non-diffused x-ray signals received from a perturbed object due to an illumination of the perturbed object.

Method 300 may start by step 310 of calculating a non-perturbed object that represents the perturbed object, wherein the non-perturbed object includes one or more regions of variable permittivity that represent one or more perturbed object regions of uniform permittivity.

Step 310 may be followed by step 320 of calculating an estimated field of the non-perturbed object.

Step 320 may be followed by step 330 of evaluating the non-diffused x-ray signals based on the estimated field of the non-perturbed object.

The perturbances of the perturbed object may follow a perturbances distribution function, wherein the variable permittivity of the one or more regions are calculated based on the perturbances distribution function.

Within a region of variable permittivity—the permittivity may change in any manner—continuous, non-continuous, stepped, step graded, and the like. For simplicity of explanation some of the following examples illustrate sub-regions within the region of variable permittivity that form a stepped variation of the permittivity.

Step 310 may include replacing a perturbed object region by multiple non-perturbed object sub-regions that differ by each other by permittivity. The multiple non-perturbed object sub-regions may be are multiple layers—or may have any other shape.

The multiple non-perturbed object sub-regions may include (a) an upper perturbed sub-region that is located above a nominal surface of the perturbed object region, and (b) a lower perturbed sub-region that is located below the nominal surface of the perturbed object region.

The perturbed object has a perturbed object region that has a nominal surface. The nominal surface of the perturbed region is a non-perturbed version of the perturbed region.

The upper perturbed sub-region and the lower perturbed sub-region may have a thickness that equals a coefficient multiplied by a standard deviation of a perturbances distribution function of the perturbances of the perturbed object.

The permittivity of the upper perturbed sub-region may differs from a permittivity of the lower perturbed sub-region, and the permittivity of the upper perturbed sub-region and the permittivity of the lower perturbed sub-region are weighted sums of (a) a permittivity (ε₁) of the perturbed object region, and (b) a permittivity (ε₂) of another region that interfaced with the perturbed object region.

The following figures illustrates example for calculating the field for a non-perturbed object instead of calculating the field for a perturbed object.

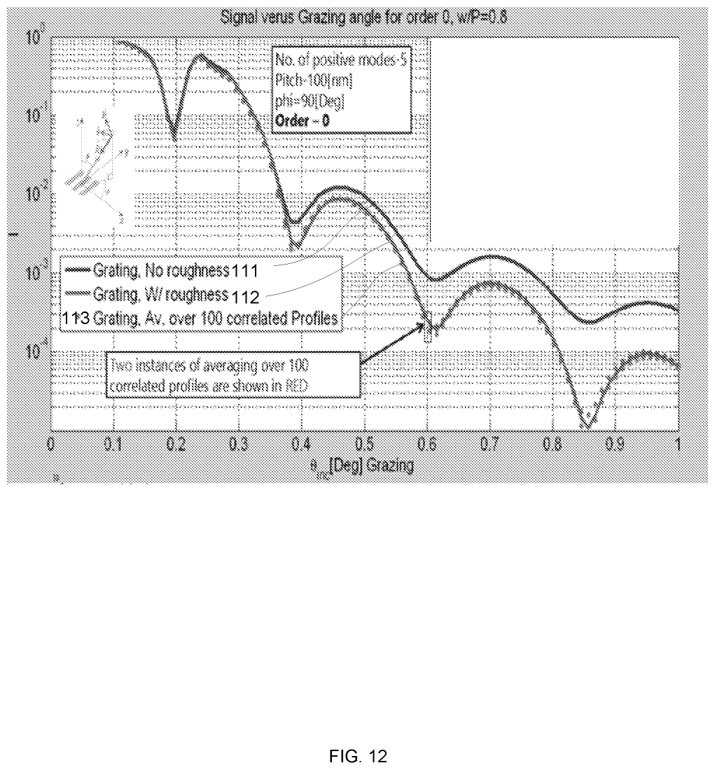

FIG. 12 illustrates an example of a signal versus grazing angle. Curve 111 illustrates this relationship for a grating (object) with no roughness, curve 112 illustrates this relationship for a perturbed object and dots 113 illustrate the relationship for an evaluation based on N=one hundred non-perturbed objects that represent the perturbed object.

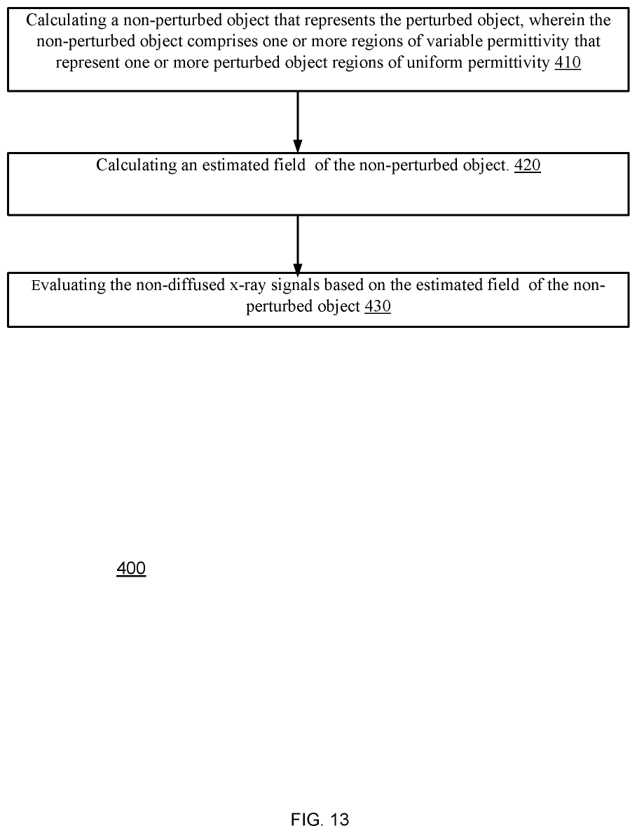

FIG. 13 illustrates an example of method 400.

Method 410 may start by step 410 of calculating a non-perturbed object that represents the perturbed object, wherein the non-perturbed object comprises one or more regions of variable permittivity that represent one or more perturbed object regions of uniform permittivity.

Step 410 may be followed by step 420 of calculating an estimated field of the non-perturbed objects.

Step 420 may be followed by step 430 of Evaluating the non-diffused x-ray signals based on the estimated field of the non-perturbed object.

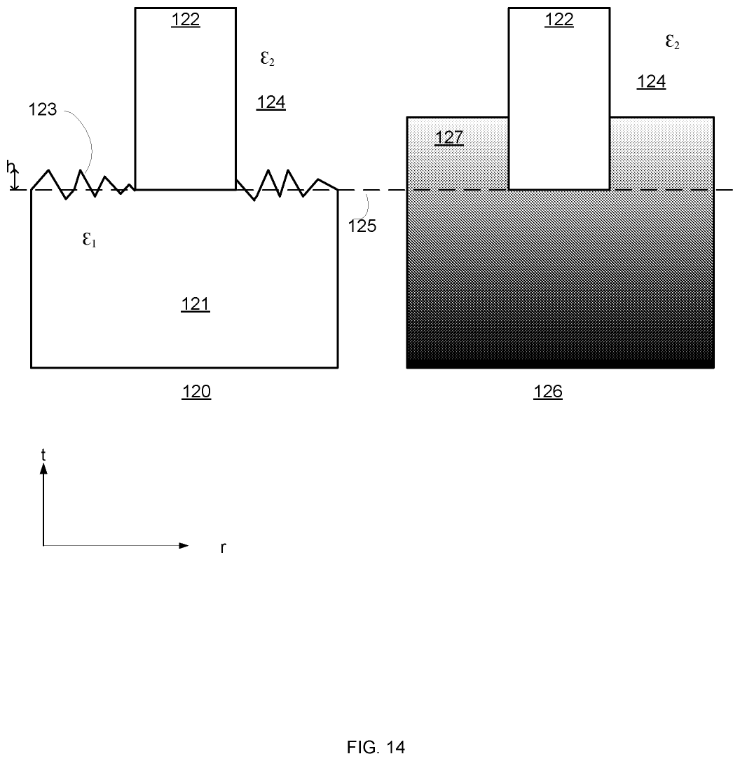

FIG. 14 illustrates a perturbed object 120 and a non-perturbed object 126 having a non-perturbed region 127 of variable permittivity.

Perturbed object 120 includes a perturbed region 121 (of uniform permittivity ε₁) that has a rough surface 123. The reflected field—averaged over many of these profiles—and characterized by having a common perturbation distribution function (taken to be Gaussian in the example of the figure) is equivalent to the field obtained from the non-perturbed object 126 that has a non-perturbed region 127 of variable permittivity—for example has a graded-perturbed object that is orthogonal to the plane of the rough surface 123 of perturbed object 120. The graded permittivity is a weighed sum that varies along the normal according to the accumulated-distribution-function, which in the case of FIG. 14 may be an error-function and a complementary error-function.

The perturbed object 120 includes a perturbed region 121 (of uniform permittivity ε₁) that has a rough surface 123, and also includes other region 122. The perturbed object interfaces with a surroundings 124 (air or another object) having another permittivity (ε₂).

The non-perturbed object 126 has a non-perturbed region 127 of variable permittivity and the other region 122. The value of the permittivity per each point of the non-perturbed region 127 of variable permittivity is represented by the gray scale at this point.

$$f ( h ) = \{ probaility distribution function of h \} = \frac{1}{\sqrt{2 π} * σ} exp ( - \frac{{h}^{2}}{2 {σ}^{2}} )$$

$${ε}_{eff} = {ε}_{1} * ( {\int }_{- ∞}^{t} f ( h ) dh ) + {ε}_{2} * ( {\int }_{t}^{∞} f ( h ) dh )$$

There is provided a method that may require to dissect a profile of an object along it axial (up-down) direction to form layers each of uniform permittivity.

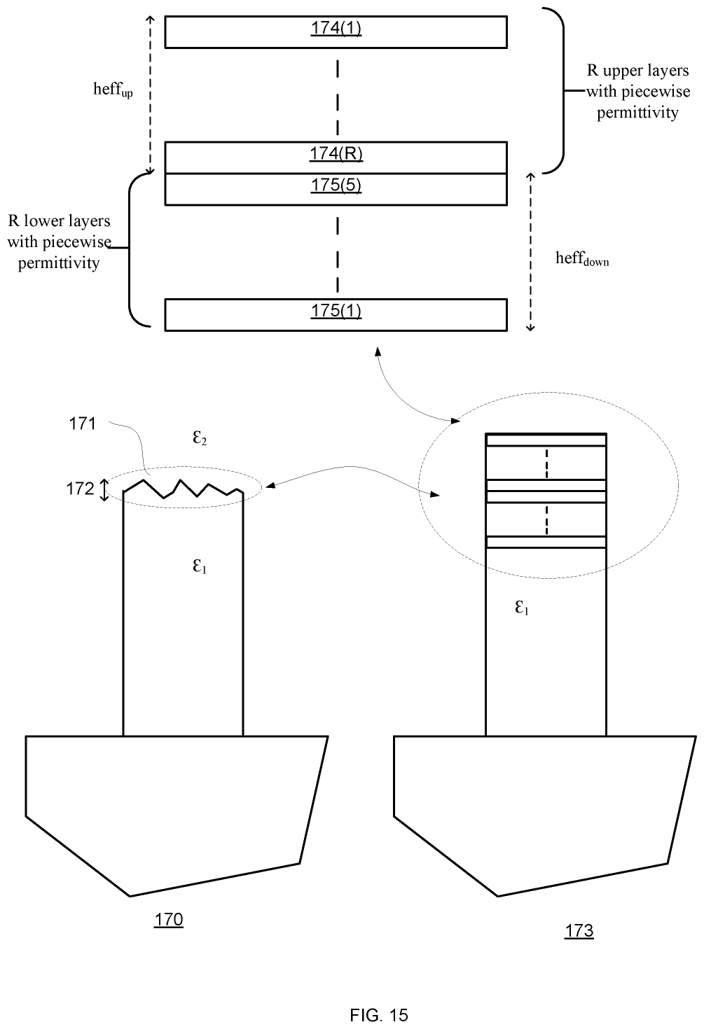

FIG. 15 illustrates an example of a perturbed object 170 having a top region of permittivity ε1 and has a rough interface 171. The height distribution of the rough surface has a standard deviation σ.

The perturbed object 170 is represented by a non-perturbed object 173 and the rough interface is represented by a plurality (R) of upper layers 174(1)-174(R) and a plurality (R) of lower layers 175(1)-175(R). The permittivity of the upper layers is determined by the accumulated-distribution-function, and the distance of this layer from a plane that represents the rough interface.

The total height of all the upper layers is denoted hᵤₚ

The total height of all the lower layers is denoted h_{down}

The effective permittivity of all the layers is denoted ε and is a function of variable t—which represents a location in relation to the nominal top surface (smooth).

$$ε = {ε}_{2} * ( \frac{1}{2} + \frac{1}{2} ( erf ( \frac{t}{\sqrt{2 σ}} ) + {ε}_{1} * ( \frac{1}{2} - \frac{1}{2} ( erf ( \frac{t}{\sqrt{2 σ}} )$$

$${h}_{up} = {h}_{down} = 4 σ$$

By varying the number of layers chosen, one can approximate the graded-index profile with ever increasing accuracy.

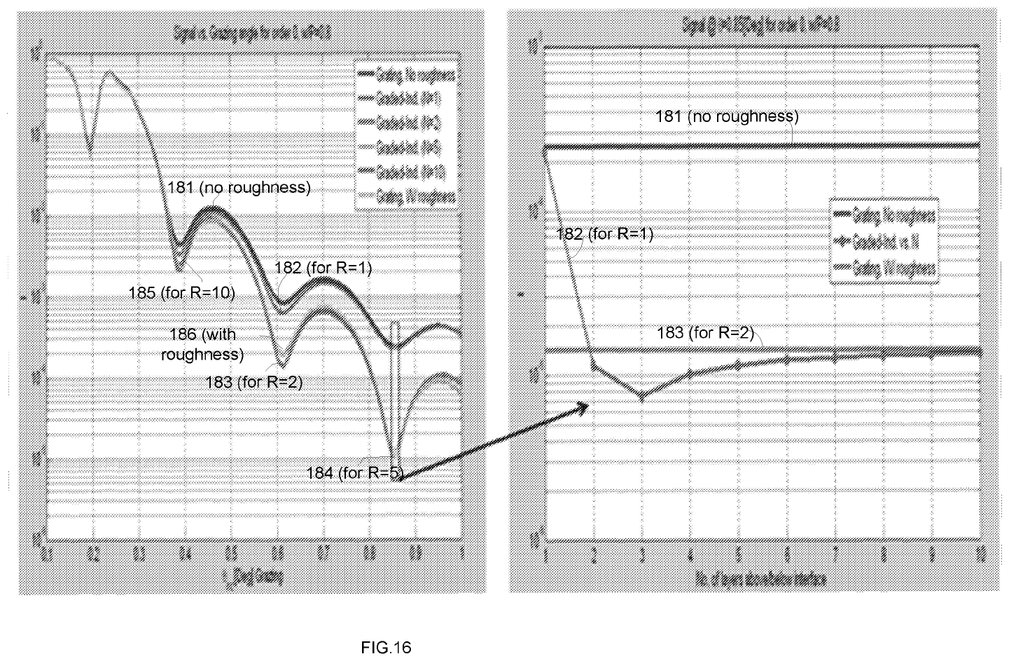

FIG. 16 illustrates an example of a signal versus grazing angle for zero order of field.
a. Non-perturbed object—curve 181.
b. Object with R=1—curve 182.
c. Object with R=2—curve 183.
d. Object with R=5—curve 184.
e. Object with R=10—curve 185.
f. Object with roughness—curve 186.

FIG. 16 illustrates that the more layer used, the more accurate the graded-index is approximated. The right graphs of FIG. 16 concentrates on one particular angle-of-incidence, and shows how by increasing the number of layers (curve 182) approximates better the rigorous result (curve 181). For reference—curve 181 represents a non-perturbed object.

The calculation time related to the evaluation of the field scales with the number of layers, and it may be desired to reduce the number of layers to speed-up calculation time.

In order to do that in the case of a rough interface, without sacrificing accuracy, there may be a need to optimize the thickness and dielectric constants of the layers by requiring these to best match the effect of the perturbation up to some given order of the field with the normal-distance from the interface.

To best match to second order in the field, it is found that the use of a single layer above and a single layer below the interface, with specific thicknesses (that scale with the roughness), and specific dielectric constants (that are some fixed weighted sum of the dielectric constants of the material above and below the roughness-free interface) may be used.

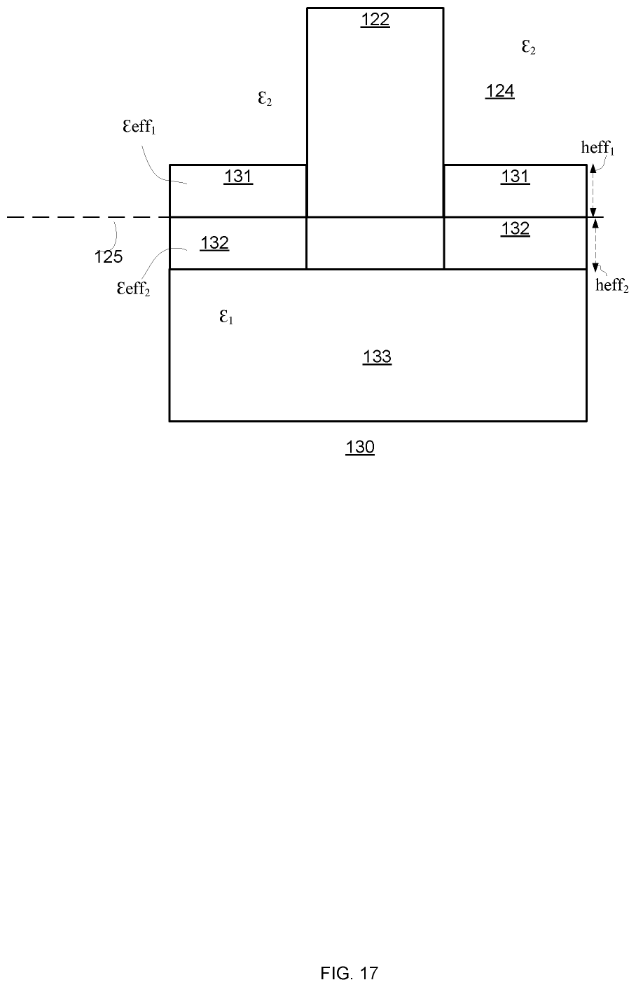

Each of the two layers may include two segments—to the right and to the left of the center of the object. S, for example FIG. 17.

FIG. 17 illustrates an example of a non-perturbed object 130 that includes bottom region 133 (having a shape of an inverted T), lower layer 131, upper layer 132, and other region 122. The lower layer 131 and upper layer 132 represent a single perturbed region (denoted 121 in FIG. 14). The interface between the lower layer and the upper layer 132 is located at a plane 125 that represents a nominal surface of the perturbed region.

The height of the upper layer 132 is denoted h_{eff1}, the height of the bottom layer 132 is denoted h_{eff2}, the permittivity of the upper layer is denoted ε_{eff1}, and the permittivity of the bottom layer is denoted ε_{eff2}.

$$f ( h ) = \{ probaility distribution function of h \} = \frac{1}{\sqrt{2 π} * σ} exp ( - \frac{{h}^{2}}{2 {σ}^{2}} )$$

$${ε}_{eff 1} = {ε}_{2} * ( 1 - \frac{1}{π} ) + {ε}_{1} * ( \frac{1}{π} )$$

$${ε}_{eff 2} = {ε}_{2} * ( \frac{1}{π} ) + {ε}_{1} * ( 1 - \frac{1}{π} )$$

$${h}_{eff 1} = {h}_{eff 2} = \sqrt{\frac{π}{2}} σ$$

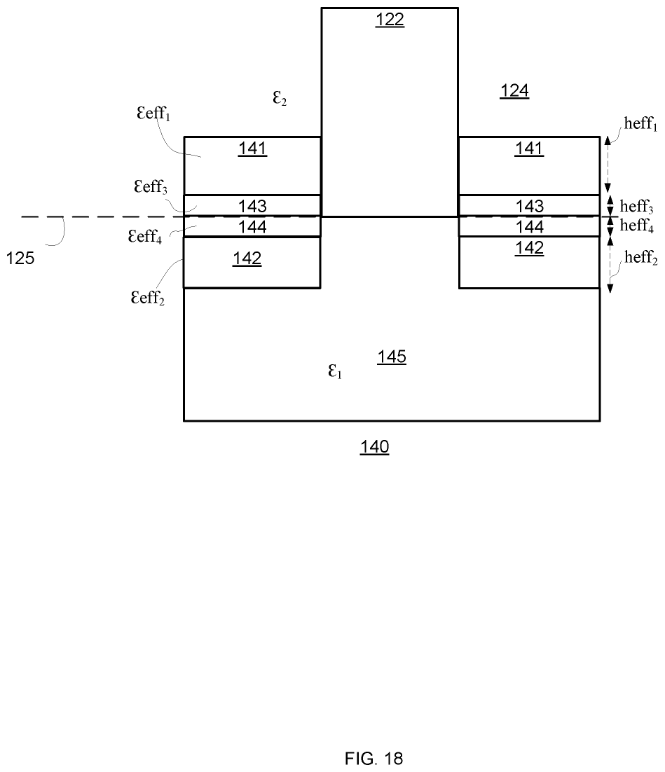

To best match the field up to fourth order, two upper layers and two upper layers are required—as illustrated in FIG. 18.

FIG. 18 illustrates an example of a non-perturbed object 140 that includes bottom region 145 (having a shape of an inverted T), lowest layer 142, lower layer 144, top layer 141, upper layer 143, and other region 122. The lowest layer 142, lower layer 144, top layer 141, and upper layer 143 represent a single perturbed region (denoted 121 in FIG. 14).

The height of the top layer 141 is denoted h_{eff1}, the height of the lowest layer 142 is denoted h_{eff2}, the height of the upper layer 143 is denoted h_{eff3}, and the height of the lower layer 144 is denoted h_{eff4}.

The permittivity of the top layer 141 is denoted ε_{eff1}, the permittivity of the lowest layer 142 is denoted ε_{eff2}, the permittivity of the upper layer 143 is denoted ε_{eff3}, and the permittivity of the lower layer 144 is denoted ε_{eff4}.

$$( h ) = \{ probaility distribution function of h \} = \frac{1}{\sqrt{2 π} * σ} exp ( - \frac{{h}^{2}}{2 {σ}^{2}} )$$

$${ε}_{eff 1} ≅ 0.065 {ε}_{1} + 0.935 {ε}_{2}$$

$${ε}_{eff 2} ≅ 0.935 {ε}_{1} + 0.065 {ε}_{2}$$

$${ε}_{eff 3} ≅ 0.401 {ε}_{1} + 0.599 {ε}_{2}$$

$${ε}_{eff 4} ≅ 0.599 {ε}_{1} + 0.401 {ε}_{2}$$

$${h}_{eff 1} = {h}_{eff 2} = ( 2.15 - 0.773 ) σ$$

$${h}_{eff 3} = {h}_{eff 4} = 0.7 \; 73 σ$$

$${h}_{eff 1} = {h}_{eff 2} = \sqrt{\frac{π}{2}} σ$$

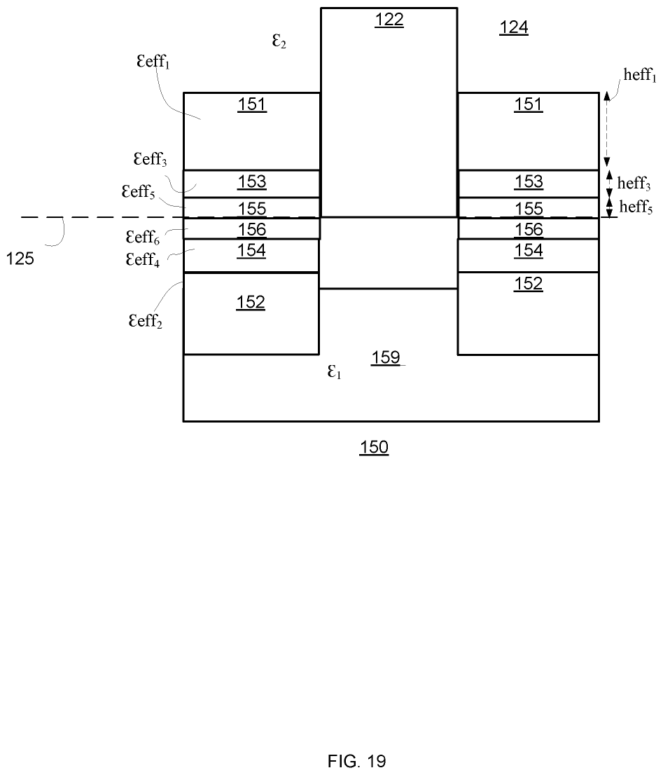

To best match the field up to sixth order, three upper layers and three upper layers are required—as illustrated in FIG. 19.

FIG. 19 illustrates an example of a non-perturbed object 150 that includes bottom region 159 (having a shape of an inverted T), lowest layer 152, lower intermediate layer 154, lower layer 156, top layer 151, upper intermediate layer 153, upper layer 155, and other region 122. The lowest layer 152, low intermediate layer 154, lower layer 156, top layer 151, upper intermediate layer 153, and upper layer 155, represent a single perturbed region (denoted 121 in FIG. 14).

The height of the top layer 151 is denoted h_{eff1}, the height of the lowest layer 152 is denoted h_{eff2}, the height of the upper intermediate layer 153 is denoted h_{eff3}, the height of the lower intermediate layer 154 is denoted h_{eff4}, the height of the upper layer 155 is denoted h_{eff5}, the height of the lower layer 156 is denoted h_{eff6}.

The permittivity of the top layer 151 is denoted ε_{eff1}, the permittivity of the lowest layer 152 is denoted ε_{eff2}, the permittivity of the upper intermediate layer 153 is denoted ε_{eff3}, the permittivity of the lower intermediate layer 154 is denoted ε_{eff4}, the permittivity of the upper layer 155 is denoted ε_{eff5}, the permittivity of the lower layer 156 is denoted ε_{eff6}.

$$( h ) = \{ probaility distribution function of h \} = \frac{1}{\sqrt{2 π} * σ} exp ( - \frac{{h}^{2}}{2 {σ}^{2}} )$$

$${ε}_{eff 1} ≅ 0.0133 {ε}_{1} + 0.9867 {ε}_{2}$$

$${ε}_{eff 2} ≅ 0.987 {ε}_{1} + 0.0133 {ε}_{2}$$

$${ε}_{eff 3} ≅ 0.1796 {ε}_{1} + 0.8204 {ε}_{2}$$

$${ε}_{eff 4} ≅ 0.8204 {ε}_{1} + 0.1796 {ε}_{2}$$

$${ε}_{eff 5} ≅ 0.4514 {ε}_{1} + 0.5486 {ε}_{2}$$

$${ε}_{eff} ≅ 0.5486 {ε}_{1} + 0.4514 {ε}_{2}$$

$${h}_{eff 1} = {h}_{eff 2} = ( 2.7735 - 1.4321 - 0.456 ) σ$$

$${h}_{eff 3} = {h}_{eff 4} = ( 1.4321 - 0.456 ) σ$$

$${h}_{eff 5} = {h}_{eff 6} = 0.456 σ$$

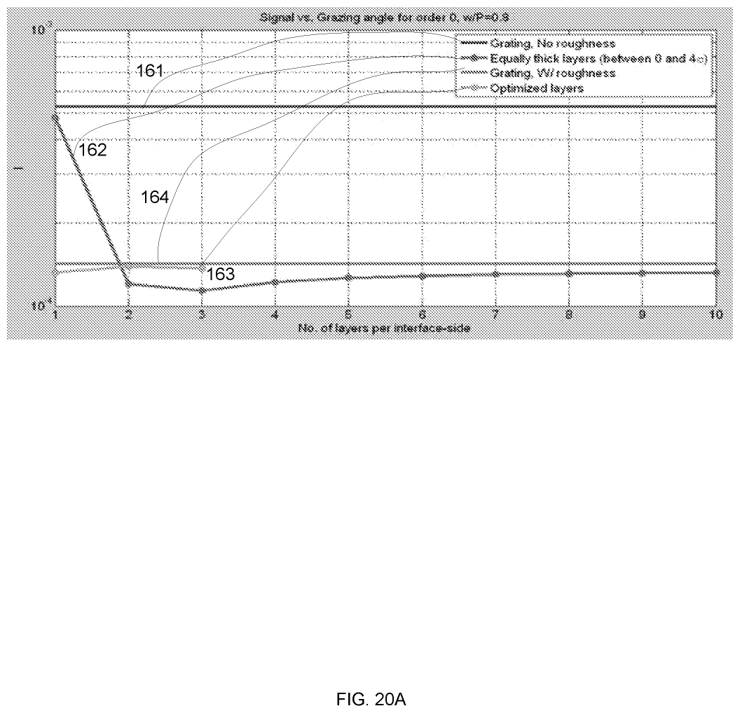

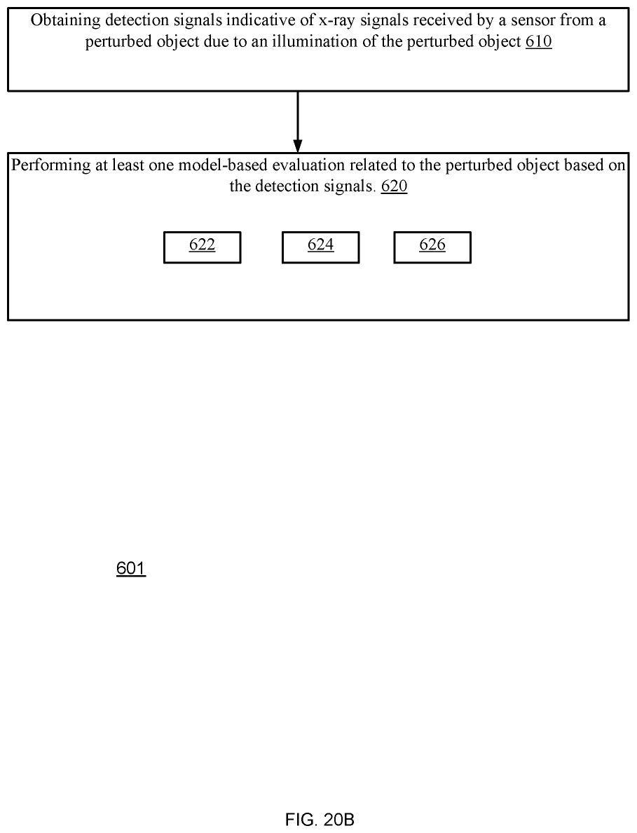

FIG. 20A illustrates an example of signal versus grazing angle for a non-perturbed object (curve 161), when using a graded permittivity approach (representing a perturbed region with layers of thickness between zero and 4σ)—see curve 162, wherein the object is routh—curve 163, and for optimal layers—see curve 164.

FIG. 20B illustrates an example of method 601.

Method 601 may include steps 610, 620 and 630.

Step 610 may include obtaining detection signals indicative of x-ray signals received by a sensor from a perturbed object due to an illumination of the perturbed object.

The obtaining may include generating the detection by the sensor, simulating the detection signals, or receiving the detection signals from a storage unit or any other source.

Step 610 may be followed by step 620 of performing at least one model-based evaluation related to the perturbed object based on the detection signals.

Step 620 may include step 622 of comparing the detection signals to reference detection signals associated with reference models of reference perturbed objects associated with one or more reference parameters.

The reference models may be calculated using any steps of method 200, 300 and 400.

Step 622 may be followed by step 624 of selecting one or more selected reference models of reference perturbed objects and determining parameters of the perturbed object based on the parameters of the one or more selected reference models of reference perturbed objects. Any selection parameter may be sued—best matching, distance based selection, and the like.

Step 624 may be followed by step 626 of setting the one or more parameters of the perturbed object to be the one or more parameter of a selected reference perturbed objects that is modeled by the selected reference model. This may include applying interpolation, interpolation, weighted sum, using a statistical function, of any other function when there are more one selected reference models.

The one or more parameters of the perturbed object may be related to roughness, related to a dimension of the perturbed object, and the like.

A reference model may be calculated by any manner—for example by applying any step of methods 200, 300 and 400.

Step 620 may include at least one out of:
a. Measuring the roughness of the perturbed object.
b. Measuring the roughness of the perturbed object, and (b) an performing an additional evaluation related to the perturbed object.
c. Performing the additional evaluation based on the roughness of the perturbed object.
d. Measuring a dimension related to the perturbed object.
e. Determining, based on a diffused signal, a standard deviation of the roughness of the perturbed object and a correlation length of the roughness.
f. Determining a non-diffused based model of the perturbed signal based on the correlation.
g. Following an obtaining a model of the perturbed object—amending the model. The model is determined based on the field, and the one or more statistical properties of the perturbances.
h. Following an obtaining a model of the perturbed object—amending the model. The model is based on additional information regarding the perturbed model. The additional information is not based on the detection signals indicative of x-ray signals.
i. Evaluating a diffused based roughness of the perturbed object.
j. Amending a non-diffused based model of the perturbed object.

U.S. Pat. No. 9,588,066, which is incorporated herein by reference illustrates a system for measuring periodic structures. A periodic structure include repetitions of a basic cell. Examples of basic cells are illustrated in the previous figures and text and also are illustrated in the following text and figures.

The system illustrated in U.S. Pat. No. 9,588,066 may be modified to apply any of the methods illustrated above. Additionally or alternatively—the measurements made by the system illustrated in U.S. Pat. No. 9,588,066 may be used as inputs to the methods illustrated above.

Embodiments pertain to methods and systems for measuring periodic structures using multi-angle X-ray reflectance scatterometry (XRS).

In an embodiment, a method of measuring a sample by X-ray reflectance scatterometry involves impinging an incident X-ray beam on a sample having a periodic structure to generate a scattered X-ray beam, the incident X-ray beam simultaneously providing a plurality of incident angles and a plurality of azimuthal angles. The method also involves collecting at least a portion of the scattered X-ray beam.

In another embodiment, a system for measuring a sample by X-ray reflectance scatterometry includes an X-ray source for generating an X-ray beam having an energy of approximately 1 keV or less. The system also includes a sample holder for positioning a sample having a periodic structure. The system also includes a monochromator positioned between the X-ray source and the sample holder. The monochromator is for focusing the X-ray beam to provide an incident X-ray beam to the sample holder. The incident X-ray beam simultaneously has a plurality of incident angles and a plurality of azimuthal angles. The system also includes a detector for collecting at least a portion of a scattered X-ray beam from the sample.

Methods and systems for measuring periodic structures using multi-angle X-ray reflectance scatterometry (XRS) are described. In the following description, numerous specific details are set forth, such as X-ray beam parameters and energies, in order to provide a thorough understanding of embodiments of the present invention. It will be apparent to one skilled in the art that embodiments of the present invention may be practiced without these specific details. In other instances, well-known features such as entire semiconductor device stacks are not described in detail in order to not unnecessarily obscure embodiments of the present invention. Furthermore, it is to be understood that the various embodiments shown in the Figures are illustrative representations and are not necessarily drawn to scale.

One or more embodiments described herein are directed to the use of an X-ray source configured in a manner that exploits simultaneous multiple incoming beam angles incident on a periodic (grating) structure for X-ray reflectance scatterometry measurements. Embodiments may enable detection of scattered light in two angular directions, as well as the use of reflected X-ray intensities to infer the shape and pitch of a periodic structure. Embodiments may provide suitable precision and stability measurements of the shape and size of complex two-dimensional (2D) and three-dimensional (3D) periodic structures in a production fab semiconductor environment. Such measurements may include shape profile of the periodic structures, and dimensions such as width, height and side-wall angle of the periodic structures.

To provide context, state-of-the-art shape metrology solutions utilize optical techniques with either single-wavelength or spectral sources nominally greater than 150 nanometers in wavelength. Spectral solutions are typically of fixed wavelength, and single wavelength sources that can vary in incident angle. Such solutions are in a wavelength/energy regime where λ>d, where λ is the incident light source, and d is the fundamental dimension of the periodic structure. However, optical scatterometry is approaching its fundamental sensitivity limits.

In accordance with an embodiment, by using wavelengths of light where λ/d<1, higher order scattering orders are available for detection, and provide direct sensitivity to the parameter d. More specifically, by using wavelengths of light less than the width and height of the structures being measured, interference fringes of multiple cycles are available, and provide sensitivity to height, width and line shape. In an embodiment, by using multiple angles of incidence as well as azimuthal angles (e.g., relative to the direction of structure symmetry), three-dimensional information is obtained, providing three-dimensional shape sensitivity. The information obtained concerns dimensions that can critically affect device performance, and need to be controlled to very tight tolerances.

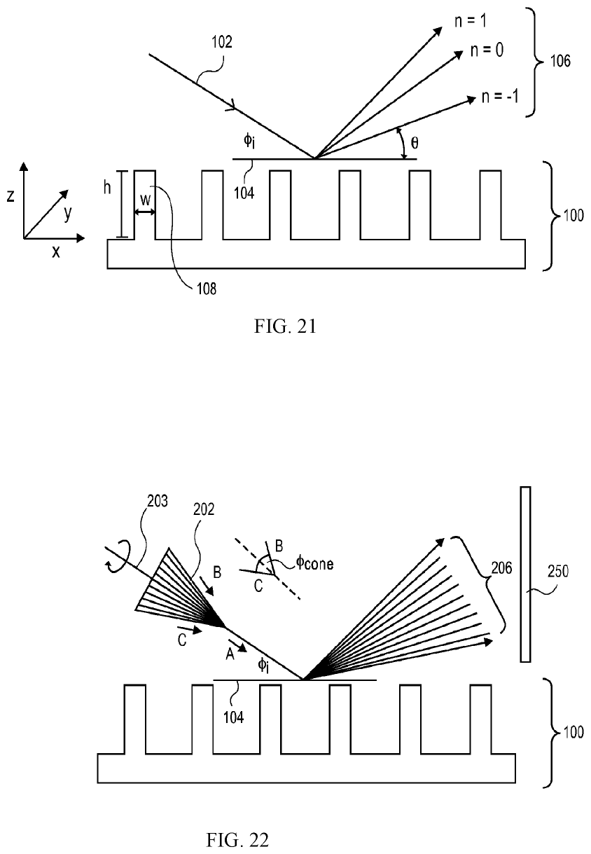

In order aid in conceptualizing concepts involved herein, FIG. 21 illustrates a cross-sectional view of a periodic structure subjected to conventional scatterometry measurements using an incident beam having a single angle of incidence. Referring to FIG. 21, a periodic structure 100 (also referred to as a grating structure) is subjected to a light beam 102. The light beam 102 has an angle of incidence, φi, relative to a horizontal plane 104 of the uppermost surface of the periodic structure 100. Scattered beams 106 are generated from the periodic structure 100. The scattered beams 106 may include beams of differing scattered angle, each providing a different order of information of the periodic structure 100. For example, as shown in FIG. 21, three orders, n=1, n=0, n=−1, are shown, where the scattered angle for the n=−1 order has an angle of θ relative to the horizontal plane 104 of the uppermost surface of the periodic structure 100. The arrangement of FIG. 21 is illustrative of conventional OCD or GISAS scatterometry approaches.

It is to be appreciated that use of the terms “periodic” or “grating” structure throughout refers to structures that are non-planar and, in some contexts, can all be viewed as three-dimensional structures. For example, referring again to FIG. 21, the periodic structure 100 has features 108 that protrude in the z-direction by a height, h. Each feature 108 also has a width, w, along the x-axis and a length along the y-axis (i.e., into the page). In some contexts, however, the term “three-dimensional” is reserved to describe a periodic or grating structure having a length along the y-axis that is on the same order as the width, w. In such contexts, the term “two-dimensional” is reserved to describe a periodic or grating structure having a length along the y-axis that is substantially longer than the width, w, e.g., several orders of magnitude longer. In any case, a periodic or grating structure is one having a non-planar topography within a region of measurement of, e.g., a semiconductor wafer or substrate.

In contrast to FIG. 21, FIG. 22 illustrates a cross-sectional view of a periodic structure subjected to scatterometry measurements using an incident beam having multiple angles of incidence, in accordance with an embodiment. Referring to FIG. 22, the periodic structure 100 is subjected to a conical X-ray beam 202. The conical X-ray beam 202 has a central axis 203 having an angle of incidence, φi, relative to the horizontal plane 104 of the uppermost surface of the periodic structure 100. As such, the conical X-ray beam 202 includes a portion, A, that has an incident angle φi. The conical X-ray beam 202 has a converging angle, φcone, which is taken between outermost portion, B, and outermost portion, C, of the conical beam 202. Since the conical X-ray beam 202 has the converging angle φcone, portions of the conical beam 202 near the outer portion of the cone have a different angle of incidence on the structure 100 than the portions of the conical X-ray beam 202 that are aligned with the central axis 202. Accordingly, the conical X-ray beam 202 simultaneously provides multiple angles of incidence for impinging on the periodic structure 100, as taken relative to the horizontal plane 104. A scattered beam 206 is generated from the periodic structure 100. The scattered beam 206 may include portions attributable to different orders of information of the periodic structure 100, examples of which are described in greater detail below.

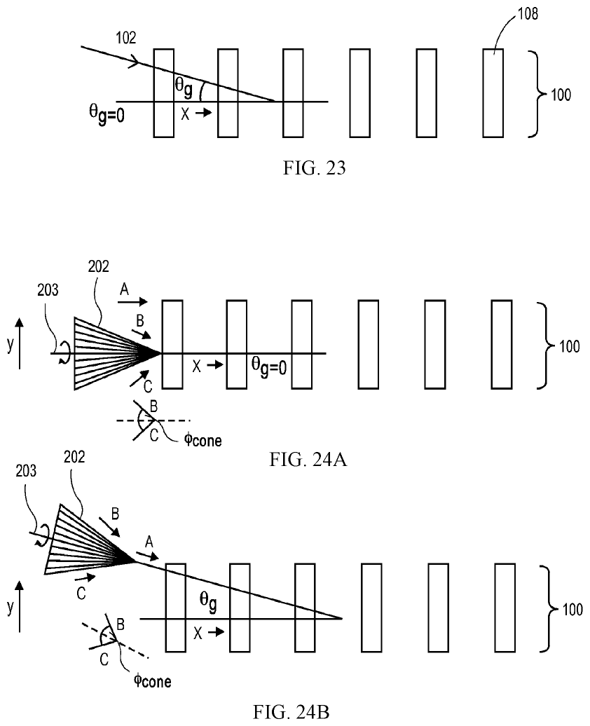

In addition to having an angle of incidence, an incident light beam can also have an azimuthal angle with respect to a periodic structure. Again for conceptual purposes, FIG. 23 illustrates a top-down view of a periodic structure subjected to conventional scatterometry measurements using an incident beam having a single azimuthal angle. Referring to FIG. 23, the periodic structure 100 is shown from above the protruding portions 108. Although not viewable in FIG. 21, the incident light beam 102 can further have an azimuthal angle, θg, relative to a direction, x, which is orthogonal to the protrusions 108 of the periodic structure 100. In some cases, θg is non-zero, as is depicted in FIG. 23. In cases where θg is zero, the direction of the light beam 102 is along the x-direction, with respect to the top-down view. In all cases where conventional OCD or GISAS scatterometry approaches applied, however, the beam 102 has only one angle, θg. Thus, taking FIGS. 21 and 23 together, conventionally, scatterometry is performed using a light beam having a single angle of incidence, φi, and a single azimuthal angle, θg.

In contrast to FIG. 23, FIGS. 24A and 24B illustrate top-down views of a periodic structure subjected to scatterometry measurements using an incident beam having multiple azimuthal angles, in accordance with an embodiment. Referring to both FIGS. 24A and 24B, the periodic structure 100 is subjected to the conical X-ray beam 202 having the central axis 203, as described in association with FIG. 22. Although not viewable from FIG. 22, the conical X-ray beam 202 further has dimensionality along the y-direction. That is, the converging angle, φcone, taken between outermost portion, B, and outermost portion, C, of the conical beam 202, also provides a plurality of incident angles along the y-direction, e.g., to provide non-zero azimuthal angles of incidence.

Referring only to FIG. 24A, the central axis of the conical X-ray beam 202 has an angle θg of zero along the x-direction, with respect to the top-down view. As such, the portion A the conical X-ray beam 202 has a zero azimuthal angle. Nonetheless, the portions B and C of the conical X-ray beam 202 have non-zero azimuthal angles even though the central axis 203 of the conical X-ray beam 202 is orthogonal to the periodic structure 100.

Referring only to FIG. 24B, the central axis of the conical X-ray beam 202 has a non-zero angle, θg, along the x-direction, with respect to the top-down view. As such, the portion A the conical X-ray beam 202 has a non-zero azimuthal angle. Additionally, the portions B and C of the conical X-ray beam 202 have non-zero azimuthal angles different from the azimuthal angle of portion A of the beam 202.

In both cases illustrated in FIG. 24A and FIG. 24B, since the conical beam 202 has the converging angle φcone, portions of the conical beam 202 near the outer portion of the cone have a different azimuthal angle incident on the periodic structure 100 than the portions of the conical beam 202 that are aligned with the central axis 202. Accordingly, the conical beam 202 simultaneously provides multiple azimuthal angles for impinging on the periodic structure 100, as taken relative to the x-direction.

Thus, taking FIG. 22 and one of FIG. 24A or 24B together, in accordance with an embodiment, a method of measuring a sample by X-ray reflectance scatterometry involves impinging an incident X-ray beam on a sample having a periodic structure. The X-ray beam has a conical shape to simultaneously provide multiple angles of incidence, Yi, and multiple azimuthal angles, θg, as incident on the periodic structure. The impinging generates a scattered X-ray beam, a portion of which (if not all) can be collected in order to glean information about the periodic structure.

In an embodiment, the incident X-ray beam is a converging X-ray beam having a converging angle, φcone, approximately in the range of 20-40 degrees. In one such embodiment, a central axis of the converging X-ray beam has a fixed non-zero incident angle, φi, and an azimuthal angle, θg, of zero relative to the sample, as was described in association with FIG. 24A. In another such embodiment, a central axis of the converging X-ray beam has a fixed non-zero incident angle, φi, and a non-zero azimuthal angle, θg, relative to the sample, as was described in association with FIG. 24B. In either case, in a specific embodiment, the central axis of the converging X-ray beam has the fixed non-zero incident angle approximately in the range of 10-15 degrees from horizontal. In another specific embodiment, the outermost portion of the conical shape of the beam and closest portion to the periodic structure, e.g., portion C as shown in FIG. 22, has an angle of approximately 5 degrees relative to a horizontal plane of the periodic structure.

In other embodiments, an example of which is described in greater detail below, it may be preferable to use a narrower conical shape. For example, in an embodiment, the incident X-ray beam is a converging X-ray beam having a converging angle approximately in the range of 2-10 degrees. In one such embodiment, a central axis of the converging X-ray beam has a fixed non-zero incident angle, φi, and an azimuthal angle, θg, of zero relative to the sample, as was described in association with FIG. 24A. In another such embodiment, a central axis of the converging X-ray beam has a fixed non-zero incident angle, φi, and a non-zero azimuthal angle, θg, relative to the sample, as was described in association with FIG. 24B.

In an embodiment, a low energy X-ray beam is impinged on the periodic structure. For example, in one such embodiment, the low energy X-ray beam has an energy of approximately 1 keV or less. Use of such a low energy source can allow for larger incident angles yet with a smaller achievable spot size. In one embodiment, the low energy X-ray beam is a Kα beam generated from a source such as, but not limited to, carbon (C), molybdenum (Mo) or Rhodium (Rh).

In an embodiment, the low energy X-ray beam is focused using a toroidal multilayer monochromator prior to impinging on the periodic structure. In one such embodiment, the monochromator provides an incident angle range of approximately +/−30 degrees and an azimuth angle range of approximately +/−10 degrees. In a specific such embodiment, the toroidal multilayer monochromator provides an incident angle range of approximately +/−20 degrees. It is to be appreciated that the conical X-ray beams described herein may not, or need not, be collimated. For example, in one embodiment, between focusing the beam at the above described monochromator and impinging the focused beam on the periodic sample, the beam is not subjected to collimation. In one embodiment, the focused low energy X-ray beam is impinged on the sample at an incident angle range less than the angle of a nominal first-order angle at zero degrees.

Referring again to FIG. 22, in an embodiment, at least a portion of the scattered X-ray beam 206 is collected using a detector 250. In one such embodiment, a two-dimensional detector is used to simultaneously sample scattered signal intensity of the portion of the scattered X-ray beam 206 scattered from the plurality of incident angles and the plurality of azimuthal angles. The collected signal may then be subjected to scatterometry analysis, e.g., where inversion of scatter data is compared to theory to determine structural details of the periodic structure 100. In one such embodiment, a shape of the periodic structure of a sample is estimated by inversion of scattering solutions relative to the sampled scattered signal intensity, e.g., by rigorously solving Maxwell's equations on the periodic structure. In an embodiment, the X-ray beam impinged on the sample has a wavelength less than a periodicity of the periodic structure 100. Thus, the probing wavelength is comparable to or less than fundamental structural dimensions, providing a richer set of data from the scattered beam 206 as compared to OCD scatterometry.

As described above, in an embodiment, the incident conical X-ray beam used for XRS is a converging X-ray beam having a converging angle, φcone, approximately in the range of 20-40 degrees. Such a relatively broad cone angle may generate a scattered beam that includes higher order diffraction data in addition to zero-order reflection data. Thus, in one embodiment, both zero order and higher order information are obtained in parallel with a single impinging operation.

In other scenarios, it may be desirable to separate zero order reflection data from higher order diffraction data. In one such embodiment, a relatively narrower cone angle may be used, e.g., the incident X-ray beam is a converging X-ray beam having a converging angle approximately in the range of 2-10 degrees. More than one single measurement may be performed using the relatively narrower cone angle. For example, in one embodiment, a first measurement is made where the central axis of the converging beam has an azimuthal angle of zero, as described in association with FIG. 24A. A second measurement is then made where the central axis of the converging beam has a non-zero azimuthal angle, as described in association with FIG. 24B. In a specific embodiment, in a sequential manner, the first measurement is performed to collect 0th order but not 1st order diffraction data for a sample having a periodic structure. The second measurement is performed to collect 1st order but not 0th order diffraction data for a sample having a periodic structure. In this way, zero order data can be separated from higher order data at the time of generating the scattered beam.

Pertaining again to both the parallel and sequential approaches, in accordance with embodiments described herein, X-ray reflectance scatterometry is used to separate different orders on an array detector by approaching in a non-zero azimuth. In many cases it is the higher orders that are more useful. By cleanly obtaining all the orders in parallel, in one case, throughput can be enhanced. However, sequential approaches may also be used. Furthermore, a very focused beam is used to probe at a variety of incidence angles rather than at a single angle of incidence. In one embodiment, the beam is not collimated since for a collimated beam, a sample would require rotation with data taken serially. By capturing a higher order, use of a very small incidence angle is not needed in order to obtain a strong reflected beam. By contrast, in an embodiment, an angle of incidence of, e.g., 10 degrees to 15 degrees can be used even in the case where a specular (0-order) reflected beam is relatively weak but the −1 order, for example, is very strong.

In either case described above, whether collected in parallel or sequentially, embodiments described herein can be used to acquire data from both the zero order (specular) reflection and from the diffracted (higher) orders. Conventional solutions have emphasized using either zero order or diffracted (higher) orders, but not both. Embodiments described herein can further be distinguished from prior disclosed scatterometry approaches, a couple examples of which are described below.

In a first previously described approach, U.S. Pat. No. 7,920,676 to Yun et al. describes a CD-GISAXS system and method. The described approach involves analyzing the diffraction pattern of scattered X-rays generated from a collimated beam and analyzing multiple orders of the diffracted light. Lower energy is used to provide a higher-convergence beam because the diffraction orders are spaced farther apart. However, the orders are still fairly closely spaced and the convergence angles described are in micro-radians. Furthermore, diffraction is not collected for a multitude of incidence angles.

By contrast, in accordance with one or more embodiments described herein, a wide range of incidence angles is used in a single beam. In the present approach, diffracted orders (other than zero-order) do not actually have to be captured to be useful. However, the +/−1 orders can have different sensitivities to grating characteristics (in particular, the pitch), so, in one embodiment, at least one extra order is captured when possible. Even so, the bulk of the information is contained in the way the signal varies with incident angle. By contrast, in the U.S. Pat. No. 7,920,676, essentially one incident angle is used and information is gathered by looking at a multiplicity of diffracted orders.

Furthermore, in accordance with one or more embodiments described herein, the first order beam can be separated from the zero-order beam by moving the first-order beam to the side of the zero-order beam. In one such embodiment, the periodic or grating structure is approached at a non-zero azimuthal angle. In this way, a highly converging beam can be used while still achieving order separation. In an exemplary embodiment, by approaching the grating at a 45° azimuth angle (for the central axis of the converging beam), the +/−1 order diffracted beams are deflected to the side of the zero-order beam by a minimum of 10 degrees, and even more as the incidence angle is increased. In this case, a convergent beam of up to approximately 10 degrees can be used while avoiding overlap or data. It is to be appreciated that depending on the specifics of the grating pitch and the X-ray energy, the separation between orders can be made to be larger or smaller. Overall, in an embodiment, by collecting a multiplicity of incident and azimuthal angles simultaneously, more useful information is obtained than compared to a single shot of a collimated beam.

In a second previously described approach, U.S. Pat. No. 6,556,652 to Mazor et al. describes measurement of critical dimensions using X-rays. The described approach is not actually based on the diffraction of an X-ray beam at all. Instead, a “shadow” is created in a collimated beam. The shadow reflects off of a pattern (e.g., a linear grating structure). The contrast mechanism for the shadow is the difference in the critical angle for reflecting x-rays between a Si region at the bottom of a grating gap and the critical angle when passing first through ridge material (photoresist). By contrast, in accordance with embodiments described herein, a majority of information comes from signals at angles far above the critical angle.

As mentioned briefly above, and exemplified below, X-ray reflectance scatterometry (XRS) can be viewed as a type of X-ray reflectometry (XRR) as applied to two-dimensional and three-dimensional periodic or grating structures. Traditional XRR measurements involve the use of a single source X-ray that probes a sample over a range of angles. Varying optical path length differences with angle provides interference fringes that can be discerned to glean film property information such as film thickness and film density. However, in XRR, physics of the X-ray interaction with matter at higher source energies limits the angular range to a grazing incidence of typically less than approximately three degrees relative to sample horizontal plane. As a result, XRR has had limited production/inline viability. By contrast, in accordance with embodiments described herein, application of low-energy XRR/XRS enables the use of larger angles due to changing optical film properties with energy that lead to larger angles of signal sensitivity.

In an exemplary application of low energy XRS, fundamental semiconductor transistor building blocks may be measured and analyzed. For example, a critical dimension (CD) of a semiconductor device refers to a feature that has a direct impact on device performance or its manufacturing yield. Therefore, CDs must be manufactured or controlled to tight specifications. Examples of more conventional CDs include gate length, gate width, interconnect line width, line spacing, and line width roughness (LWR). Semiconductor devices are very sensitive to such dimensions, with small variations potentially leading to substantial impacts on performance, device failure, or manufacturing yield. As integrated circuit (IC) feature sizes of semiconductor devices continue to shrink, manufacturers face ever decreasing process windows and tighter tolerances. This has dramatically raised the accuracy and sensitivity requirements for CD metrology tools as well as the need for non-destructive measurement sampling early in the manufacturing cycle with minimal impact to productivity of the semiconductor device manufacturing plant or fab.

Non-planar semiconductor device fabrication has complicated matters even further. For example, semiconductor devices fabricated on raised channels having a non-planar topography often referred to as fins further include fin dimensions as additional CDs that must be accounted for. Such fin field effect transistor (fin-FET) or multi-gate devices have high-aspect ratio features, and the need for three-dimensional (3D) profile information on the fins of device structures, including sidewall angle, and top and bottom dimensions, has become critical. Consequently, the ability to measure the 3D profile provides far more valuable information than the conventional two-dimensional line width and spacing CD information.

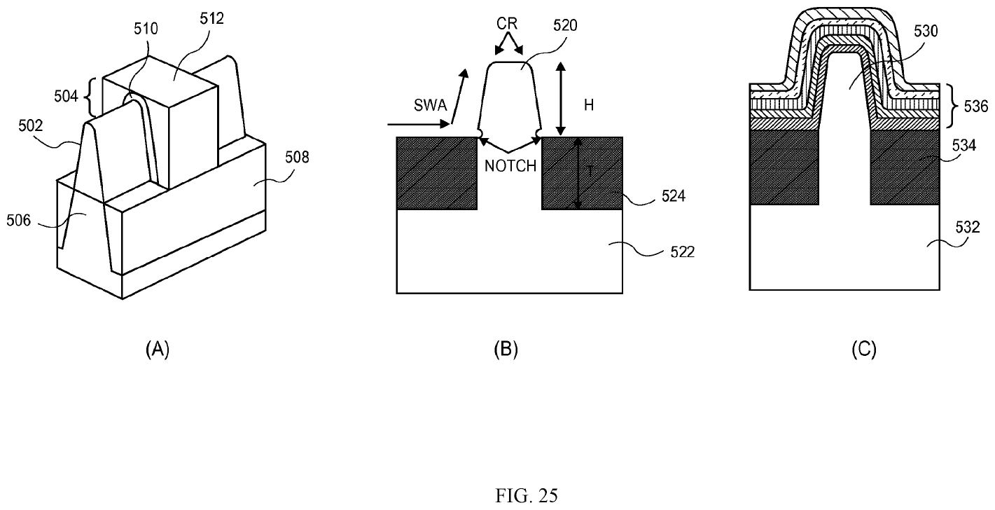

FIG. 25 illustrates aspects of exemplary fin-FET devices suitable for low energy X-ray reflectance scatterometry measurements, in accordance with an embodiment. Referring to FIG. 25, structure A illustrates an angled cross-sectional view of a semiconductor fin 502 having a gate electrode stack 504 disposed thereon. The semiconductor fin 502 protrudes from a substrate 506 which is isolated by shallow trench isolation (STI) regions 508. The gate electrode stack 504 includes a gate dielectric layer 510 and a gate electrode 512. Structure B illustrates a cross-sectional view of a semiconductor fin 520 protruding from a substrate 522 between STI regions 524. Aspects of structure B that may provide important information through XRS measurements include fin corner rounding (CR), fin sidewall angle (SWA), fin height (H), fin notching (notch), and STI thickness (T), all of which are depicted in structure B of FIG. 25. Structure C illustrates a cross-sectional view of a semiconductor fin 530 protruding from a substrate 532 between STI regions 534, and having a multilayer stack of films 536 thereon. The layers of the multilayer stack of films 536 may include material layers such as, but not limited to, titanium aluminum carbide (TiAlC), tantalum nitride (TaN) or titanium nitride (TiN). Comparing structures B and C, XRS measurements may be performed on a bare fin such as a bare silicon fin (structure B), or on a fin having different material layers disposed thereon.

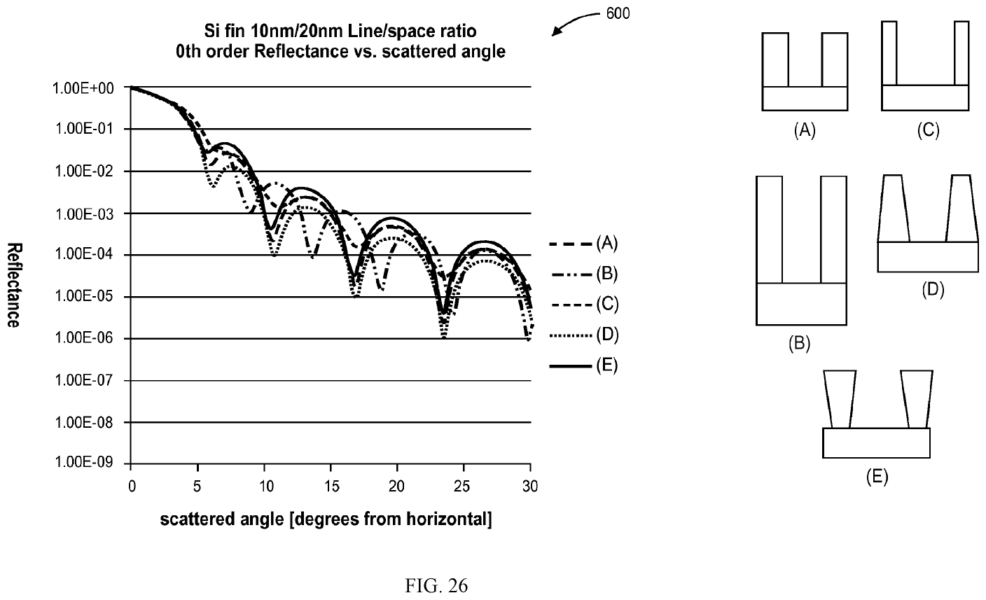

FIG. 26 includes a plot 600 and corresponding structures (A)-(E) of 0th order reflectance versus scattered angle silicon (Si) fins having a periodic structure with 10 nm/20 nm line/space ratio, in accordance with an embodiment. Referring to FIG. 26, low energy XRS measurements can be used to distinguish between a nominal fin structure (structure A), a structure of increased fin height (structure B), a structure of decreased fin width (structure C), a structure of wider fin bottom CD versus fin top CD (structure D), and a structure of narrower fin bottom CD versus fin top CD (structure E). In this exemplar case, the Si fins are analyzed with 0th order conical diffraction at 45 degrees to the periodic structure. It is to be appreciated that, in comparison to optical data, a reduced region of highest signal is achieved with fringes in data seen in plot 600 being a consequence of short wavelength.

FIG. 27 includes a plot 700 and corresponding structures (A)-(E) of 1st order reflectance versus scattered angle silicon (Si) fins having a periodic structure with 10 nm/20 nm line/space ratio, in accordance with an embodiment. Referring to FIG. 27, low energy XRS measurements can be used to distinguish between a nominal fin structure (structure A), a structure of increased fin height (structure B), a structure of decreased fin width (structure C), a structure of wider fin bottom CD versus fin top CD (structure D), and a structure of narrower fin bottom CD versus fin top CD (structure E). In this exemplar case, the Si fins are analyzed with 1st order conical diffraction at 45 degrees to the periodic structure. Additionally, a structure of varying pitch has been included in plot 700. As shown in plot 700, 1st order data is very sensitive to fin thickness (noting that structure B is separated significantly from the signals due to structures A and C-E). Also, 1st order data is very sensitive to pitch variation in the periodic structure, noting that the spectrum for varied pitch is also significantly discernible from the other spectra.

In another aspect, an apparatus for performing X-ray reflectance scatterometry is described. In general, in an embodiment, such an apparatus includes a generic X-ray source along with a focusing monochromator that extends in two dimensions. The focusing monochromator allows for incident rays of light to strike a periodic sample at two varying incident angles, (i) incident to the plane of the periodic structure, and (ii) azimuthally, with respect to the symmetry of the structure (and at fixed incident angle). The detection of the scattered light is achieved by a two-dimensional (2D) detector, which simultaneously samples the scattered signal intensity across the range of scattered angles in the two angular directions. In one embodiment, the constraints of the monochromator that assure the detected signal is free of scattering order-overlap require that the incident angle range be less than the angle of the nominal first-order angle at 0 degree, i.e., θ=sin−1 (1−λ/d). As a result of the use of light with a characteristic wavelength smaller than the period of the grating, higher order diffraction orders are accessible, and provide additional information regarding the grating structure. In addition, interference fringes of multiple thickness cycles are available to determine line height, width and shape. The final estimation of the shape and structure of the periodic structure is achieved via inversion of the scattering solutions compared to the 2D interference/scatter data.

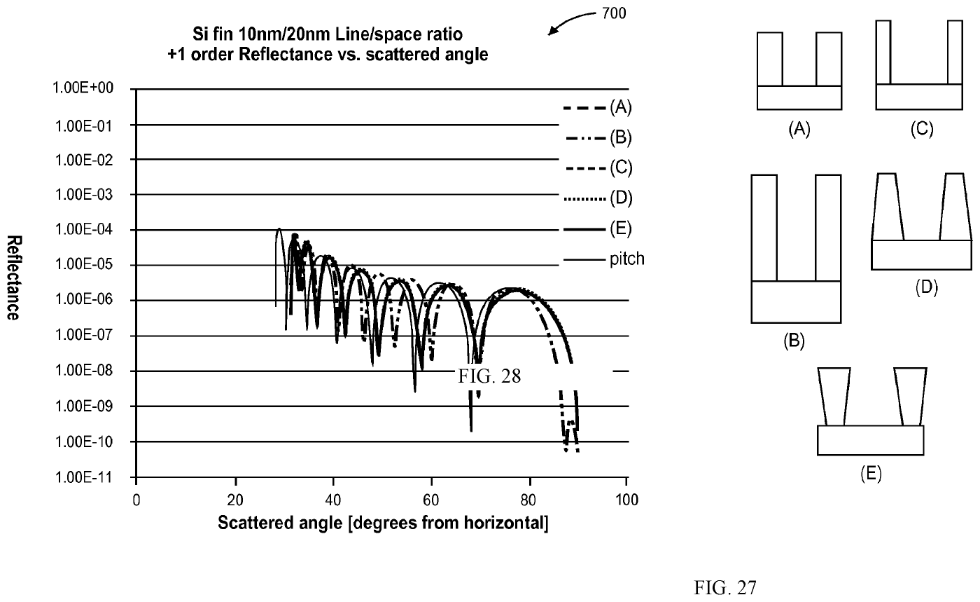

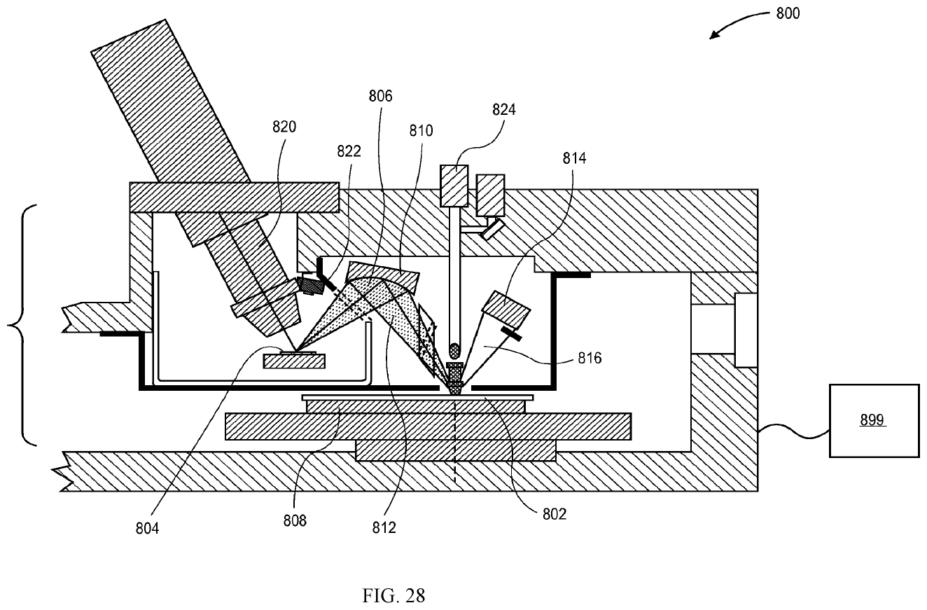

As a more specific example, FIG. 28 is an illustration representing a periodic structure measurement system having XRS capability, in accordance with an embodiment.

Referring to FIG. 28, a system 800 for measuring a sample 802 by X-ray reflectance scatterometry includes an X-ray source 804 for generating an X-ray beam 806 having an energy of approximately 1 keV or less. A sample holder 808 is provided for positioning the sample 802, the sample having a periodic structure. A monochromator 810 is positioned between the X-ray source 804 and the sample holder 802, in that the X-ray beam 806 travels from the X-ray source 804 to the monochromator 810 and then to the sample holder 808. The monochromator 810 is for focusing the X-ray beam 806 to provide an incident X-ray beam 812 to the sample holder 808. The incident X-ray beam 812 simultaneously has a plurality of incident angles and a plurality of azimuthal angles. The system 800 also includes a detector 814 for collecting at least a portion of a scattered X-ray beam 816 from the sample 802.

Referring again to FIG. 28, in an embodiment, the X-ray source 804, the sample holder 808, the monochromator 810 and the detector 814 are all housed in a chamber 818. In an embodiment, the system 800 further includes an electron gun 820. In one such embodiment, the X-ray source 804 is an anode and the electron gun is directed at the anode. In a particular embodiment, the anode is for generating low energy X-rays and includes a material such as, but not limited to, carbon (C), molybdenum (Mo) or Rhodium (Rh). In one embodiment, the electron gun 820 is an approximately 1 keV electron gun. Referring again to FIG. 28, a magnetic electron suppression device 822 is included between the X-ray source 804 and the monochromator 810.

In an embodiment, the monochromator 810 is a toroidal multilayer monochromator that provides an incident angle range of approximately +/−30 degrees and an azimuth angle range of approximately +/−10 degrees. In one such embodiment, the toroidal multilayer monochromator provides an incident angle range of approximately +/−20 degrees. In an embodiment, as described above, there is no intervening collimator between the monochromator 810 and the sample holder 808. The monochromator 810 may be positioned to provide a desired incident beam for XRS measurements. For example, in a first embodiment, the monochromator 810 is positioned relative to the sample holder 808 to provide a converging X-ray beam having a central axis with a fixed non-zero incident angle and an azimuthal angle of zero relative to a periodic structure of a sample 802. In a second embodiment, the monochromator 810 is positioned relative to the sample holder 808 to provide a converging X-ray beam having a central axis with a fixed non-zero incident angle and a non-zero azimuthal angle relative to a periodic structure of a sample 802. In an embodiment, the monochromator 810 is composed of alternating metal (M) layers and carbon (C) layers disposed on a glass substrate, where M is a metal such as, but not limited to, cobalt (Co) or chromium (Cr). In a particular such embodiment, a multilayer monochromator is provided for reflecting carbon (C) based Kα radiation and includes approximately would be 100 repeating layers of Co/C or Cr/C with a period of about 4 nanometers, i.e., a period slightly less than the wavelength of the reflected beam which may be approximately 5 nanometers. In one such embodiment, the Co or Cr layers are thinner than the C layers.

The sample holder 808 may be a moveable sample holder. For example, in an embodiment, the sample holder 808 is rotatable to change an azimuth angle of a central axis of the X-ray beam 812 relative to a periodic structure of a sample 802. In an embodiment, the sample holder 808 is rotatable to provide orthogonal operation with eucentric rotation, enabling two or more sample rotations per measurement. In an embodiment, a navigation visual inspection apparatus 824 allows visual inspection of the sample holder 808, as is depicted in FIG. 28. In one such embodiment, a flip-in objective lens is included for a vision-based inspection system.

In an embodiment, the detector 814 is a two-dimensional detector. The two-dimensional detector may be configured for simultaneously sampling scattered signal intensity of the portion of the scattered X-ray beam 816 scattered from the plurality of incident angles and the plurality of azimuthal angles of the incident beam 812. In an embodiment, the system 800 further includes a processor or computing system 899 coupled to the two-dimensional detector. In one such embodiment, the processor 899 is for estimating a shape of the periodic structure of a sample 802 by inversion of scattering solutions relative to the sampled scattered signal intensity. In place of a two-dimensional detector, in another embodiment, a scanning slit may be implemented. In either case, the detector 814 can be configured to achieve approximately 1000 pixels of data collection across a dispersion range.

Embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

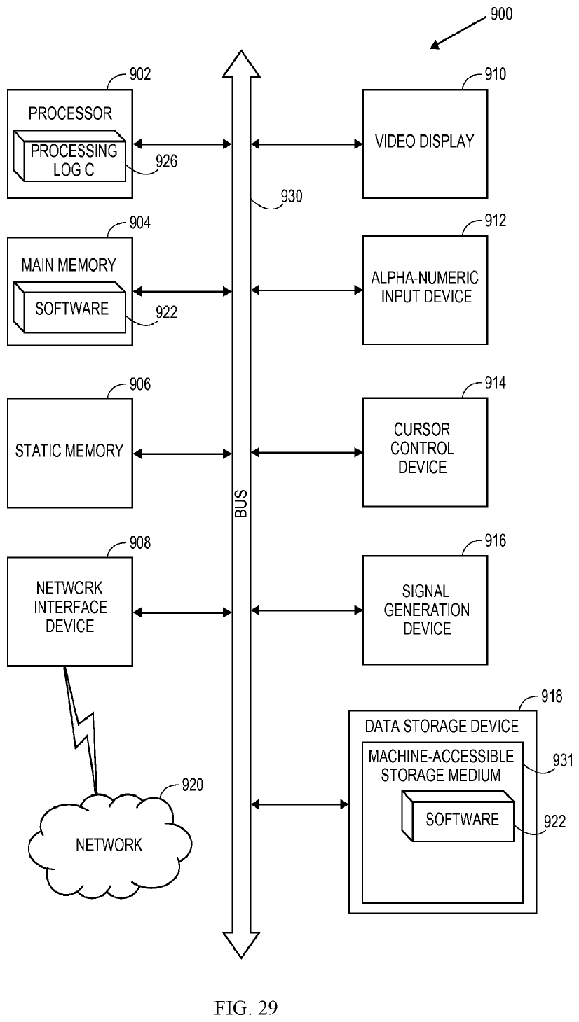

FIG. 29 illustrates a diagrammatic representation of a machine in the exemplary form of a computer system 900 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. For example, in an embodiment, a machine is configured to execute one or more sets of instruction for measuring a sample by X-ray reflectance scatterometry. In one example, the computer system 900 may be suitable for use of computer system 899 of the above described XRS apparatus 800.

The exemplary computer system 900 includes a processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

Processor 902 represents one or more general-purpose processing devices such as a microprocessor, central processing unit, or the like. More particularly, the processor 902 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 902 may also be one or more special-purpose processing devices such as an application specific integrated circuit (ASIC), a field programmable gate array (FPGA), a digital signal processor (DSP), network processor, or the like. Processor 902 is configured to execute the processing logic 926 for performing the operations discussed herein.

The computer system 900 may further include a network interface device 908. The computer system 900 also may include a video display unit 910 (e.g., a liquid crystal display (LCD) or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium (or more specifically a computer-readable storage medium) 931 on which is stored one or more sets of instructions (e.g., software 922) embodying any one or more of the methodologies or functions described herein. The software 922 may also reside, completely or at least partially, within the main memory 904 and/or within the processor 902 during execution thereof by the computer system 900, the main memory 904 and the processor 902 also constituting machine-readable storage media. The software 922 may further be transmitted or received over a network 920 via the network interface device 908.

While the machine-accessible storage medium 931 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of an embodiment. The term “machine-readable storage medium” shall accordingly be taken to include, but not be limited to, solid-state memories, and optical and magnetic media.

In accordance with an embodiment, a non-transitory machine-accessible storage medium has stored thereon instruction for performing a method of measuring a sample by X-ray reflectance scatterometry. The method involves impinging an incident X-ray beam on a sample having a periodic structure to generate a scattered X-ray beam. The incident X-ray beam simultaneously provides a plurality of incident angles and a plurality of azimuthal angles. The method also involves collecting at least a portion of the scattered X-ray beam.

Thus, methods and systems for measuring periodic structures using multi-angle X-ray reflectance scatterometry (XRS) have been described.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation; a single operation may be distributed in additional operations and operations may be executed at least partially overlapping in time. Moreover, alternative embodiments may include multiple instances of an operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

The terms “including”, “comprising”, “having”, “consisting” and “consisting essentially of” can be replaced with each other. For example—any method may include at least the steps included in the figures and/or in the specification, only the steps included in the figures and/or the specification.

We claim:

1. A method for evaluating non-diffused x-ray signals received from a perturbed object due to an illumination of the perturbed object, the method comprises:
calculating an estimated field for each of multiple non-perturbed objects, the multiple non-perturbed objects represent perturbances of the perturbed object; the perturbances are of an order of a wavelength of the non-diffused x-ray signals; and
evaluating the non-diffused x-ray signals based on the field of the multiple non-perturbed objects.

2. The method according to claim 1 wherein the perturbed object and each of the multiple non-perturbed objects has a uniform permittivity.

3. The method according to claim 1 wherein the perturbances of the perturbed object follow a perturbances distribution function, wherein the multiple non-perturbed objects are calculated based on the perturbances distribution function.

4. The method according to claim 3 wherein the perturbances distribution function is a probabilistic function of a height parameter of the perturbances of the perturbed object.

5. The method according to claim 4 wherein the height parameter of a given protuberance that is related to an interface of the perturbed object is a distance between the protuberance and the interface of the perturbed object, wherein the given protuberance belongs to the perturbances.

6. The method according to claim 4 wherein the perturbed object has a single rough interface, wherein the multiple non-perturbed objects have corresponding non-perturbed interfaces, one corresponding non-perturbed interface per each of the multiple non-perturbed objects, wherein a perturbances distribution function of the height parameter of perturbances of the single rough interface is substantially equal to a perturbances distribution function of the height parameter of corresponding given non-perturbed interfaces.

7. The method according to claim 4 wherein the perturbed object has a plurality of rough interfaces, and the multiple non-perturbed objects have corresponding non-perturbed interfaces, a plurality of corresponding non-perturbed interface per each of the multiple non-perturbed objects.

8. A non-transitory computer readable medium for evaluating non-diffused x-ray signals received from a perturbed object due to an illumination of the perturbed object, the non-transitory computer readable medium stores instructions for:
calculating an estimated field for each of multiple non-perturbed objects, the multiple non-perturbed objects represent perturbances of the perturbed object; the perturbances are of an order of a wavelength of the non-diffused x-ray signals; and
evaluating the non-diffused x-ray signals based on the field of the multiple non-perturbed objects.

9. A system for evaluating non-diffused x-ray signals received from a perturbed object due to an illumination of the perturbed object, the system comprises a processor that is configured to:
calculate an estimated field for each of multiple non-perturbed objects, the multiple non-perturbed objects represent perturbances of the perturbed object; the perturbances are of an order of a wavelength of the non-diffused x-ray signals; and
evaluate the non-diffused x-ray signals based on the field of the multiple non-perturbed objects

10. A method for evaluating non-diffused x-ray signals received from a perturbed object due to an illumination of the perturbed object, the method comprises: calculating a non-perturbed object that represents the perturbed object, wherein the non-perturbed object comprises one or more regions of variable permittivity that represent one or more perturbed object regions of uniform permittivity; calculating an estimated field of the non-perturbed object; and evaluating the non-diffused x-ray signals based on the estimated field of the non-perturbed object.

11. The method according to claim 10 wherein the perturbances of the perturbed object follow a perturbances distribution function, wherein the variable permittivity of the one or more regions are calculated based on the perturbances distribution function.

12. The method according to claim 10 wherein the one or more regions of variable permittivity have a stepped permittivity.

13. The method according to claim 10 wherein the one or more regions of variable permittivity have a stepped graded permittivity.

14. The method according to claim 10 wherein the calculating of the non-perturbed object comprises replacing a perturbed object region by multiple non-perturbed object sub-regions that differ by each other by permittivity.

15. The method according to claim 14 wherein the multiple non-perturbed object sub-regions are multiple layers.

16. The method according to claim 14 wherein the multiple non-perturbed object sub-regions comprise (a) an upper perturbed sub-region that is located above a nominal surface of the perturbed object region, and (b) a lower perturbed sub-region that is located below the nominal surface the perturbed object region.

17. The method according to claim 16 wherein the upper perturbed sub-region and the lower perturbed sub-region have a thickness that equals a coefficient multiplied by a standard deviation of a perturbances distribution function of the perturbances of the perturbed object.

18. The method according to claim 17 wherein a permittivity of the upper perturbed sub-region differs from a permittivity of the lower perturbed sub-region, and wherein the permittivity of the upper perturbed sub-region and the permittivity of the lower perturbed sub-region are weighted sums of (a) a permittivity (εᵤₚ) of the perturbed object region, and (b) a permittivity (ε_{down}) of another region that interfaced with the perturbed object region.

19. A non-transitory computer readable medium for evaluating non-diffused x-ray signals received from a perturbed object due to an illumination of the perturbed object, the non-transitory computer readable medium stores instructions for: calculating a non-perturbed object that represents the perturbed object, wherein the non-perturbed object comprises one or more regions of variable permittivity that represent one or more perturbed object regions of uniform permittivity; calculating an estimated field of the non-perturbed object; and evaluating the non-diffused x-ray signals based on the estimated field of the non-perturbed object.

20. A system for evaluating non-diffused x-ray signals received from a perturbed object due to an illumination of the perturbed object, the system comprises a processor that is configured to: calculate a non-perturbed object that represents the perturbed object, wherein the non-perturbed object comprises one or more regions of variable permittivity that represent one or more perturbed object regions of uniform permittivity; calculate an estimated field of the non-perturbed object; and evaluating the non-diffused x-ray signals based on the estimated field of the non-perturbed object.

21-46. (canceled)
